(19) United States
(12) Patent Application Publication
(10) Pub. No.: US 2025/0107274 A1
(43) Pub. Date: Mar. 27, 2025

(54) PHOTONIC DEVICE, A PHOTONIC SYSTEM COMPRISING THE PHOTONIC DEVICE AND A METHOD OF SPECTROSCOPIC SENSING USING THE PHOTONIC SYSTEM

(71) Applicant: National University of Singapore, Singapore (SG)

(72) Inventors: Junsheng XIE, Singapore (SG); Zhihao REN, Singapore (SG); Chengkuo LEE, Singapore (SG)

(21) Appl. No.: 18/483,706

(22) Filed: Oct. 10, 2023

(30) Foreign Application Priority Data
Sep. 22, 2023 (SG) 10202302695R

(51) Int. Cl. H01L 31/0232; G01R 29/24; G01R 31/265; H01L 31/0224; H01L 31/028

(52) U.S. Cl. CPC H10F 77/413; G01R 29/24; G01R 31/2656; H10F 77/122; H10F 77/206

(57) ABSTRACT

A photonic device is described in an embodiment. The photonic device comprising: a 2D material layer formed on a substrate; a source electrode and a drain electrode formed on the 2D material layer; and a plurality of nanoantennas formed on the 2D material layer between the source electrode and the drain electrode. Each of the plurality of nanoantennas having dimensions associated with a resonant wavelength of the photonic device and being configured to act as a non-centrosymmetric centre for providing anisotropy to generate a photocurrent in response to a polarized light incident on the photonic device, and the polarized light having a light wavelength near the resonant wavelength. The plurality of nanoantennas comprises one or more metal layers. The source electrode and the drain electrode are adapted to measure a photovoltage formed by the generated photocurrent, and a reduction in a magnitude of the photovoltage measured is used to detect a presence of an analyte having an absorption peak near the resonant wavelength of the photonic device. A photonic system comprising the photonic device and a method of spectroscopic sensing using the photonic system are also described.

### CROSS-REFERENCE TO RELATED APPLICATIONS

The present application claims the benefit of the filing date of Singapore Patent Application No. 10202302695R, filed Sep. 22, 2023, the disclosure of which is incorporated herein by reference.

### TECHNICAL FIELD

The present disclosure relates to a photonic device, a photonic system comprising the photonic device and a method of spectroscopic sensing using the photonic system.

### BACKGROUND

2D materials have attracted significant interest due to their intriguing photonic and electronic properties. As atomically thin films, 2D materials show immense potential in miniaturized, portable, and flexible optoelectronic devices, including photodetectors, optical sensors as well as spectrometers. Among them, 2D photodetectors have become promising candidates for miniaturized and on-chip integrated photonic platforms. Within the optical spectrum range, long-wave infrared (LWIR, e.g. 6-14 μm) processes have enormous potential for chem/bio-sensing as it covers abundant absorption fingerprints of gas/biomolecules, many of which are biomarkers for healthcare monitoring and early disease diagnosis.

Graphene is an excellent candidate for LWIR photodetectors as it is a gapless 2D material with broadband absorption. However, unlike black phosphorus and many IV-V compounds, graphene does not show in-plane anisotropy, which hinders graphene from polarization-dependent photodetectors. Moreover, graphene also suffers from low absorption in infrared (IR) of ≈2.3%, resulting in a low responsivity and poor sensing performance.

Meanwhile, optical gas/liquid sensing is a critical application for LWIR detection. Conventional optical sensors are mostly based on the spectrum information of analytes, such as spectral shift and absorption spectrum. However, these optical sensors need bulky spectrometers to collect spectral information, which hinders them from on-chip integration. Waveguide-based optical sensors with potentials to be implemented on a chip-scale level have been reported. However, they still need another commercial photodetector to detect the transmitted light to collect the sensing information.

It is therefore desirable to provide a photonic device, a photonic system comprising the photonic device and a method of spectroscopic sensing using the photonic system which address the aforementioned problems and/or provides a useful alternative.

Further, other desirable features and characteristics will become apparent from the subsequent detailed description and the appended claims, taken in conjunction with the accompanying drawings and this background of the disclosure.

### SUMMARY

Aspects of the present application relate to a photonic device, a photonic system comprising the photonic device and a method of spectroscopic sensing using the photonic system.

In accordance with a first aspect, there is provided a photonic device comprising: a 2D material layer formed on a substrate; a source electrode and a drain electrode formed on the 2D material layer; and a plurality of nanoantennas formed on the 2D material layer between the source electrode and the drain electrode, each of the plurality of nanoantennas having dimensions associated with a resonant wavelength of the photonic device and being configured to act as a non-centrosymmetric centre for providing anisotropy to generate a photocurrent in response to a polarized light incident on the photonic device, the polarized light having a light wavelength near the resonant wavelength, the plurality of nanoantennas comprising one or more metal layers; wherein the source electrode and the drain electrode are adapted to measure a photovoltage formed by the generated photocurrent, and a reduction in a magnitude of the photovoltage measured is used to detect a presence of an analyte having an absorption peak near the resonant wavelength of the photonic device.

By having the plurality of nanoantennas formed on the 2D material layer each configured to act as a non-centrosymmetric centre, the photonic device is capable of generating a photocurrent (thereby providing a photovoltage) in response to an incident polarized light having a light wavelength near the resonant wavelength of the photonic device. The measured photovoltage can then be used to detect a presence of an analyte having an absorption peak near the resonant wavelength of the photonic device, where absorption of the polarized light near the resonant wavelength by the analyte produces a reduction in a magnitude of the photovoltage measured by the photonic device. The photonic device is therefore capable of detecting a polarized light of the resonant wavelength (or around the resonant wavelength) as well as being used for spectral sensing for detecting a presence of an analyte. By integrating the function of a photodetector and an optical spectral sensor on a single platform, high efficiency, low cost, and high-level miniaturization can be achieved.

Wherein the polarized light may include a linearly polarized light, a polarity and a magnitude of the photovoltage measured may be dependent on a polarization angle of the linearly polarized light and may be adapted to indicate a polarization of the linearly polarized light.

By adapting the photonic device to indicate a polarization of the linearly polarized light, enhanced sensing performance can be achieved. Particularly, polarization relates to another dimension of light in addition to the wavelength, phase and intensity. This can provide supplementary but indispensable information for many analytes and enhance sensing performance. Polarization imaging and sensing techniques of biostructures can be applied to various biomedical applications, including early disease diagnosis and enhanced tissue imaging. Therefore, an integrated platform to realize multi-functional detection, including spectroscopic and polarimetric sensing is highly desirable. The present photonic device provides a way to achieve this.

In accordance with a second aspect, there is provided a photonic system comprising: a photonic device, the photonic device comprising: a 2D material layer formed on a substrate; a plurality of nanoantennas formed on the 2D material layer, the plurality of nanoantennas having dimensions associated with a resonant wavelength of the photonic device and being configured to act as a non-centrosymmetric centre for providing anisotropy to generate a photocurrent in response to a polarized light incident on the photonic device, the polarized light having a light wavelength near the resonant wavelength of the photonic device, the plurality of nanoantennas comprising one or more metal layers; and a source electrode and a drain electrode formed on the 2D material layer, wherein the plurality of nanoantennas are formed between the source electrode and the drain electrode on the 2D material layer, the source electrode and the drain electrode being adapted to measure a photovoltage formed by the generated photocurrent; a light source configured to provide the polarized light on the photonic device, the polarized light having a wavelength near the resonant wavelength; a chamber having an inlet adapted to allow an inflow of a gas into the chamber, an outlet adapted to allow an outflow of the gas to exit the chamber and an optically transparent window, wherein the photonic device is provided in the chamber and the optically transparent window is adapted to allow passage of the polarized light on the photonic device; and a measurement device connected to the source electrode and the drain electrode for measuring the photovoltage generated by the photonic device, wherein a reduction in a magnitude of the photovoltage measured is used to detect a presence of an analyte in the gas, the analyte having an absorption peak near the resonant wavelength of the photonic device.

Wherein the polarized light may include a linearly polarized light, a polarity and a magnitude of the photovoltage measured using the photonic device may be dependent on a polarization angle of the incident linearly polarized light and may be adapted to indicate a polarization of the linearly polarized light.

The 2D material layer may include graphene.

Each of the plurality of nanoantennas may comprise two L-shape structures, each of the two L-shape structures may have a first section and a second section perpendicular to the first section, wherein the two L-shape structures may be arranged adjacent to each other with a gap in-between them, and wherein the first section of each of the two L-shape structures may be on a longitudinal axis of the photonic device and the second section of each of the two L-shape structures may be parallel to each other and on a same side of the longitudinal axis so that the two L-shape structures are symmetrical with respect to a transverse axis of the photonic device, the transverse axis may be perpendicular to the longitudinal axis.

Wherein a length of the first section of each of the two L-shape structures and a length of the second section of each of the two L-shape structures may each be in a range of 0.5 μm to 2 μm. The length of the first section of each of the two L-shape structures may be equal to the length of the second section of each of the two L-shape structures.

Wherein the gap between the two L-shape structures may be in a range of 200 nm to 600 nm.

Wherein the light wavelength of the polarized light or the absorption peak of the analyte may be within a range of ±0.5 μm from the resonant wavelength of the photonic device.

Wherein the plurality of nanoantennas may include an array of nanoantennas and the resonant wavelengths of the photonic device may include a range of resonant wavelengths, the array of nanoantennas may include nanoantennas having varying dimensions for providing the range of resonant wavelengths of the photonic device.

The one or more metal layers may include a palladium layer and a gold layer.

The dimensions of each of the plurality of nanoantennas may be adapted to generate the photocurrent in response to the polarized light having a wavelength in a range of 6 μm to 14 μm.

In accordance with a third aspect, there is provided a method of spectroscopic sensing using one of the aforementioned photonic system, the method comprising: providing the polarized light on the photonic device; passing the gas comprising the analyte into the chamber; and measuring the photovoltage generated by the photonic device to detect a presence of the analyte in the gas.

It should be appreciated that features relating to one aspect may be applicable to the other aspects. Embodiments therefore provide a photonic device, a photonic system comprising the photonic device and a method of spectroscopic sensing using the photonic system. Particularly, by having the plurality of nanoantennas formed on the 2D material layer each configured to act as a non-centrosymmetric centre, the photonic device is capable of generating a photocurrent (thereby providing a photovoltage) in response to an incident polarized light having a light wavelength near the resonant wavelength of the photonic device. The measured photovoltage can then be used to detect a presence of an analyte having an absorption peak near the resonant wavelength of the photonic device where absorption of the polarized light near the resonant wavelength by the analyte provides a reduction in a magnitude of the photovoltage measured by the photonic device. The photonic device is therefore capable of detecting a polarized light in the resonant wavelength as well as being used for spectral sensing for detecting a presence of an analyte. By integrating the function of a photodetector and an optical spectral sensor on a single platform, high efficiency, low cost, and high-level miniaturization can be achieved. Further, the plurality of nanoantennas of the photonic device can be adapted so that a polarity and a magnitude of the photovoltage measured may be dependent on a polarization angle of a linearly polarized light for indicating a polarization of the linearly polarized light. By adapting the photonic device to provide indication of a polarization of the linearly polarized light, enhanced sensing performance can be achieved. Particularly, polarization relates to another dimension of light in addition to the wavelength, phase and intensity. This can provide supplementary but indispensable information for many analytes and enhance sensing performance. Polarization imaging and sensing techniques of biostructures can be applied to various biomedical applications, including early disease diagnosis and enhanced tissue imaging. Therefore, an integrated platform to realize multi-functional detection, including spectroscopic and polarimetric sensing is highly desirable. The present photonic device provides a way to achieve this.

### BRIEF DESCRIPTION OF THE DRAWINGS

Embodiments will now be described, by way of example only, with reference to the following drawings, in which:

FIG. 1 shows a schematic diagram of a photonic device having integrated polarimetric detection and spectroscopic sensing in accordance with an embodiment;

FIG. 2 is a schematic diagram showing a photonic device comprising nanoantennas which act as non-centrosymmetric centres formed on top of a graphene layer in accordance with an embodiment;

FIG. 3 shows an atomic force microscopy (AFM) image of one of the graphene flakes used in fabricating the photonic device of FIG. 2 in accordance with an embodiment;

FIG. 4 shows a schematic diagram of a cross-section of the photonic device of FIG. 2 in accordance with an embodiment;

FIGS. 5A and 5B show scanning electron microscopy (SEM) images of the nanoantennas comprised in the photonic device of FIG. 2 in accordance with an embodiment, where FIG. 5A shows a SEM image of a top sectional view of the photonic device comprising a plurality of nanoantennas and FIG. 5B shows a SEM image of a nanoantenna to illustrate its geometric parameters;

FIG. 6 shows a graph of measured Fourier Transform Infrared (FTIR) reflection versus wavelength of the incident polarized light of the DLNAs with different gap distances in accordance with an embodiment;

FIG. 7 shows a graph of drain current (Id) versus drain-source voltage (Vd) under different gate voltages (Vg) for the photonic device of FIG. 2 in accordance with an embodiment;

FIGS. 8A and 8B show graphs of photovoltage of the photonic device of FIG. 2 versus positions in relation to a x-axis and a y-axis for measuring an illumination spot size of the incident polarized light in accordance with an embodiment, where FIG. 8A shows a graph of photovoltage versus positions in relation to the x-axis and FIG. 8B shows a graph of photovoltage versus positions in relation to the y-axis;

FIG. 9 shows results of simulated near-field intensity for different polarization angles of an incident polarized light in accordance with an embodiment;

FIG. 10 shows schematic diagrams illustrating simulated plasmonic modes and respective predicted vectorial photocurrents at different polarization angles of an incident polarized light in accordance with an embodiment;

FIG. 11 shows a polar graph of measured photovoltage for different polarization angles of an incident polarized light in accordance with an embodiment;

FIG. 12 shows a graph of absorption spectrum of an acetone gas and a plot of reduction ratio ΔV/V0 versus a wavelength of an incident polarized light in accordance with an embodiment;

FIGS. 13A and 13B show graphs of simulated absorption and reflection for different polarization angles of an incident polarized light using finite-difference time-domain (FDTD) simulation in accordance with an embodiment, where FIG. 13A shows plots of simulated absorption for different polarization angles of the incident polarized light and FIG. 13B shows plots of simulated reflection for different polarization angles of the incident polarized light;

FIG. 14 shows graphs of measured reflection of the photonic device of FIG. 2 for different polarization angles using a Fourier Transform Infrared (FTIR) spectrometer in accordance with an embodiment;

FIGS. 15A and 15B show graphs of simulated absorption and reflection for different antenna lengths (Lx and Ly) using an incident polarized light having a polarization angle of 45° using finite-difference time-domain (FDTD) simulation in accordance with an embodiment, where FIG. 15A shows a graph of simulated absorption for the different antenna lengths and FIG. 15B shows a graph of simulated reflection for the different antenna lengths;

FIG. 16 shows a graph of measured reflection for different antenna lengths using a Fourier Transform Infrared (FTIR) spectrometer in accordance with an embodiment;

FIG. 17 shows a schematic diagram of a measurement setup for polarimetric detection using a photonic device in accordance with an embodiment;

FIG. 18 shows a graph of current versus source-drain voltage (VDS) of the photonic device of FIG. 17 in a dark condition, a first illuminated condition with a polarized light having a polarization angle of 45° and a second illuminated condition with a polarized light having a polarization angle of 135° using the measurement setup of FIG. 13 in accordance with an embodiment;

FIG. 19 shows a graph of measured drain current (Id) versus gate voltage (Vg) hysteresis curves of the photonic device of FIG. 17 in a dark condition in accordance with an embodiment;

FIG. 20 shows a graph of measured dark noise of the photonic device of FIG. 17 in accordance with an embodiment;

FIG. 21 shows a graph of measured time response of the photonic device with an incident polarized light having a polarization angle of 45° and modulated with an optical signal chopper at 1 kHz using the measurement setup of FIG. 17 in accordance with an embodiment;

FIG. 22 shows a graph of photovoltage versus frequency for measured and predicted frequency responses of the photonic device of FIG. 17 in accordance with an embodiment;

FIG. 23 shows a graph of measured photovoltage versus power of the incident polarized light at zero bias of the photonic device of FIG. 17 in accordance with an embodiment;

FIG. 24 shows a graph of measured responsivity of the photonic device of FIG. 17 versus wavelength of the incident polarized light in the long-wave infrared (LWIR) range in accordance with an embodiment;

FIG. 25 shows SEM images of three different types of devices to illustrate artificial anisotropy provided by the non-centrosymmetric nanoantennas for providing polarization dependence of a photonic device in accordance with embodiments;

FIGS. 26A and 26B show schematic diagrams for Device 2 and Device 3 and their corresponding graphs of simulated absorption spectrums respectively using an incident polarized light having a polarization angle of 90° in accordance with an embodiment;

FIG. 27 shows a graph of photovoltage versus polarization angle of an incident polarized light for the three devices of FIG. 25 in accordance with embodiments;

FIG. 28 shows a graph of photovoltage versus polarization angle of an incident polarized light for Device 2 of FIG. 25 using incident polarized lights with two different illumination powers at a wavelength of 6.5 μm in accordance with an embodiment;

FIG. 29 shows a graph of photovoltage versus polarization angle of an incident polarized light for Device 2 of FIG. 25 with a fine polarization angle measurement of 1-degree step in accordance with an embodiment;

FIGS. 30A and 30B show diagrams in relation to a photonic device used in spectroscopic sensing in accordance with an embodiment, where FIG. 30A shows a scanning electron microscopy (SEM) image of the photonic device and FIG. 30B shows a graph of simulated absorption spectrum of the photonic device;

FIG. 31 shows a schematic diagram of a photonic system comprising the photonic device of FIG. 30A for spectroscopic sensing in accordance with an embodiment;

FIG. 32 is a flowchart showing a method for spectroscopic sensing using the photonic system of FIG. 31 in accordance with an embodiment;

FIG. 33 shows a graph of normalized photo-response versus time measured by the photonic device of the photonic system of FIG. 31 when pure N2 and 750 ppm acetone-N2 dilution were alternately injected in the gas chamber in accordance with an embodiment;

FIG. 34 shows an enlarged section of the graph of normalized photo-response versus time of FIG. 33 to illustrate a gas sensing response time of the photonic system of FIG. 31 in accordance with an embodiment;

FIG. 35 shows an enlarged section of the graph of normalized photo-response versus time of FIG. 33 to illustrate a gas sensing recovery time of the photonic system of FIG. 31 in accordance with an embodiment;

FIG. 36 shows a plot of reduction ratio ΔV/V0 using pure N2 (i.e. without acetone) to illustrate a noise level of the photonic system of FIG. 31 in accordance with an embodiment;

FIG. 37 shows a graph of absorption spectrum of an acetone gas and a plot of reduction ratio ΔV/V0 of the photonic system of FIG. 31 versus a wavelength of incident polarized light in accordance with an embodiment; and

FIG. 38 shows a graph of normalized photo-response versus time measured by the photonic device of the photonic system of FIG. 31 with injection and ejection of 3250 ppm ethanol in the gas chamber in accordance with an embodiment.

### DETAILED DESCRIPTION

Exemplary embodiments relate to a photonic device, a photonic system comprising the photonic device and a method of spectroscopic sensing using the photonic system.

Graphene-antenna hybrid structures were explored in sole graphene photodetectors or sensors but few have demonstrated surface-enhanced sensing based on antenna-mediated graphene photodetectors. Further, current graphene photodetectors with graphene-antenna hybrid structures for polarimetry mainly operate in mid-wave infrared (MWIR). It is desirable to extend the operation wavelengths to the LWIR range and realize multi-function detection including polarization and molecule sensing. For example, in present embodiments, strong artificial anisotropy at the metal-graphene surfaces can be achieved by fine designing geometric structures of the nanoantenna for realizing filter-less polarization-sensitive detection.

Embodiments of the present disclosure provide a photonic device comprising (i) a two-dimensional (2D) material layer formed on a substrate, (ii) a source electrode and a drain electrode formed on the 2D material layer, and (iii) a plurality of nanoantennas formed on the 2D material layer between the source electrode and the drain electrode. Each of the plurality of nanoantennas formed on the 2D material layer is configured to act as a non-centrosymmetric centre for providing anisotropy to generate a photocurrent in response to a polarized light incident on the photonic device, where the polarized light has a light wavelength near a resonant wavelength of the photonic device. The source electrode and the drain electrode are used to measure a photovoltage formed by the generated photocurrent induced by the incident polarized light. The photonic device can therefore be used as a photodetector, particularly for detecting incident polarized light having a light wavelength near a resonant wavelength of the photonic device. In this way, the photonic device can be used to detect a presence of an analyte having an absorption peak near the resonant wavelength of the photonic device by measuring a reduction in a magnitude of the photovoltage detected by the photonic device. Further, in the above configuration, the anisotropy provided by the plurality of nanoantennas allows a detection of a polarization of the polarized light. Particularly, the presence of the anisotropy provided by the plurality of nanoantennas causes a polarity and a magnitude of the photovoltage generated by the photonic device to be dependent on a polarization angle of the polarized light. In the present embodiments, the plurality of nanoantennas comprise one or more palladium and gold metal layers but it may be appreciated that other metals can be used as long as a photocurrent can be generated in response to the incident polarized light.

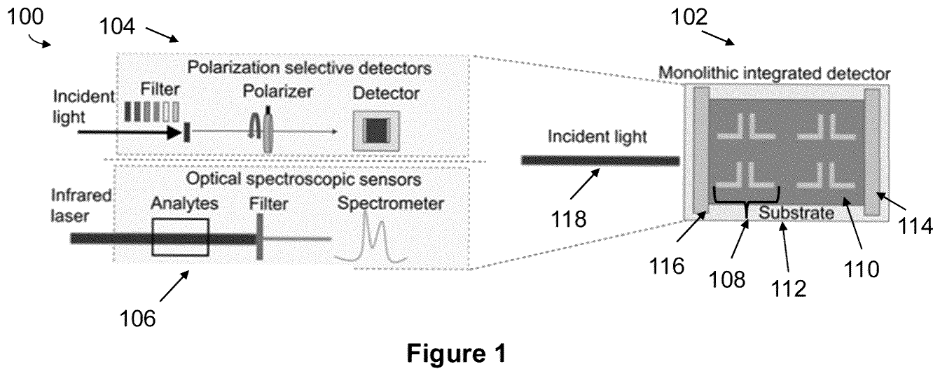

FIG. 1 shows a schematic diagram 100 of a photonic device 102 having integrated polarimetric detection 104 and spectroscopic sensing 106 in accordance with an embodiment. The polarization dependent photo-response of the photonic device 102 can be realised by an artificial anisotropy formed by an appropriately designed nanoantenna 108. As explained above, the artificial anisotropy provided by the nanoantenna 108 causes a polarity and a magnitude of the photovoltage generated by the photonic device to be dependent on a polarization angle of the polarized light. Further, also discussed above, a reduction in a magnitude of the photovoltage generated by the photonic device can also be used to detect a presence of an analyte. This can be used in spectroscopic sensing applications.

As shown in FIG. 1, in the present embodiment, an array of double L-shaped nanoantennas (DLNAs) 108 are provided on a two-dimensional (2D) material layer 110. The 2D material layer 110 is formed on a substrate 112 which provides support for the 2D material layer 110. The photonic device 102 also includes a source electrode 114 and a drain electrode 116. The source electrode 114 and the drain electrode 116 are adapted to measure a photovoltage formed by the generated photocurrent of the array of DLNAs 108.

In each application of polarimetric detection 104 and spectroscopic sensing 106, an incident polarized light 118 is used. If polarimetric detection 104 is desired, a linearly polarized light is used as the incident polarized light 118. For polarimetric detection 104, the photonic device 102 is adapted to detect a polarization angle of the linearly polarized light using a polarity and a magnitude of the photovoltage measured. For the spectroscopic sensing 106, the presence of an analyte can be detected using a reduction in the magnitude of the photovoltage generated by the incident polarized light 118 (e.g. by comparing the magnitude of the photovoltage generated in the presence of the analyte with the magnitude of the photovoltage generated in the absence of the analyte (i.e. ambient condition)). These will be discussed in more detail in relation to the exemplary embodiments below.

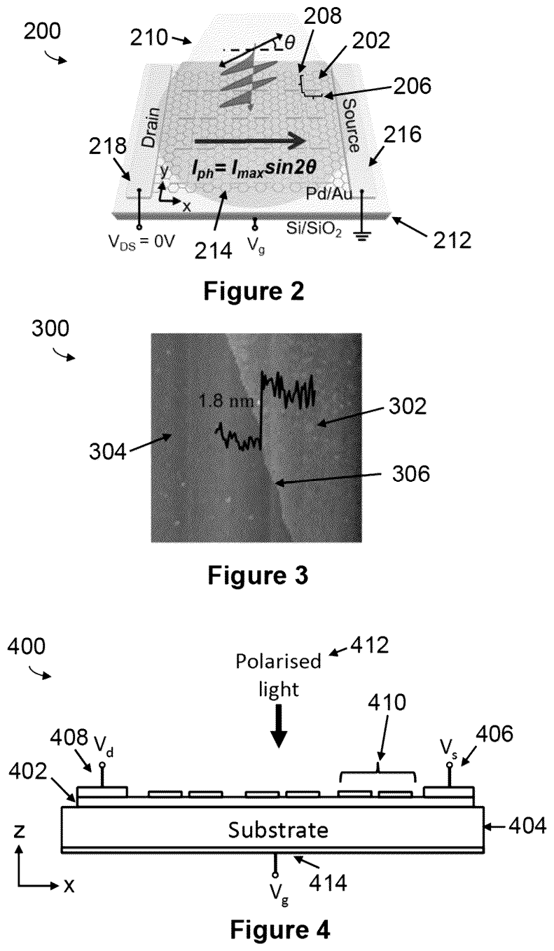

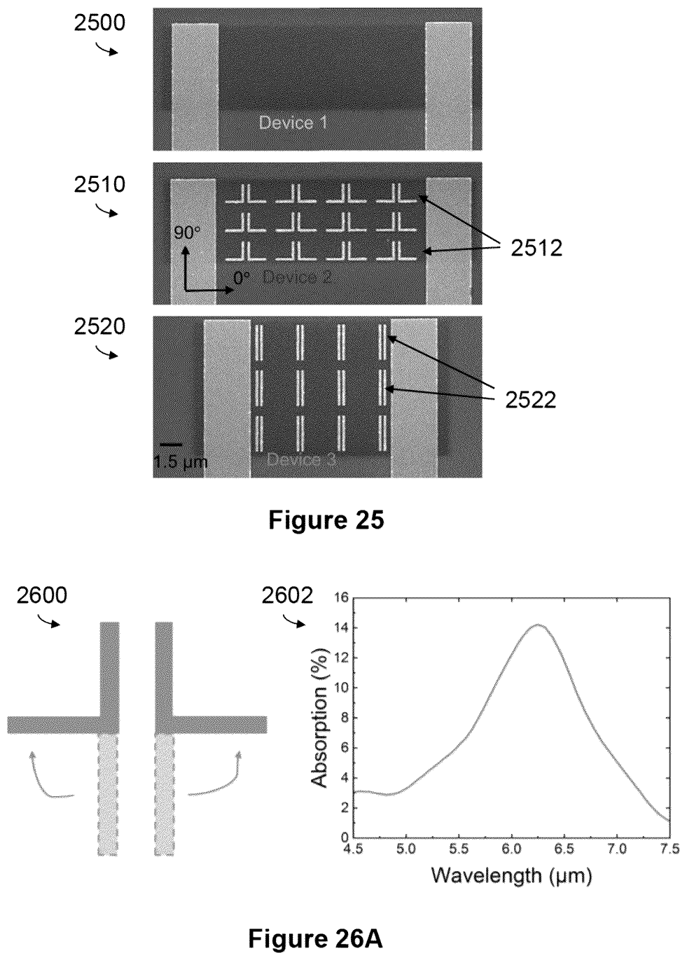

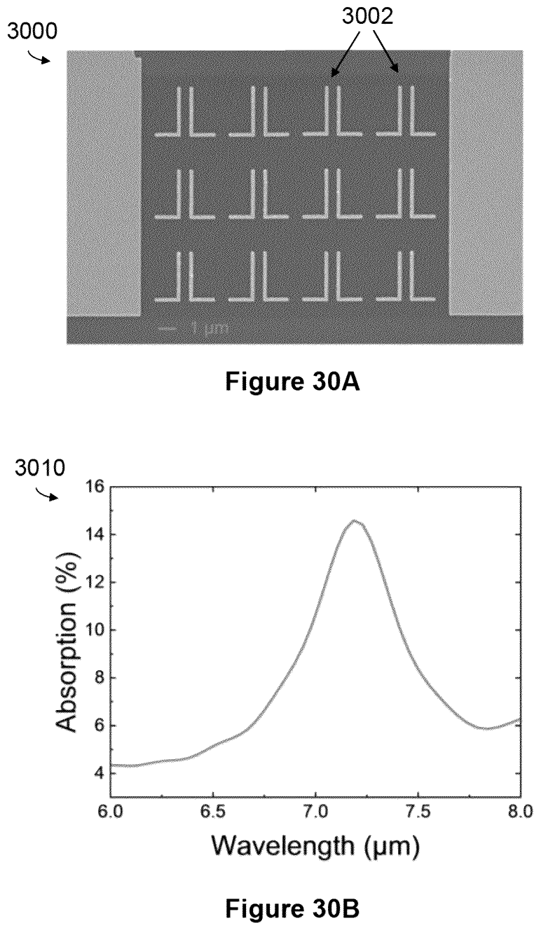

FIGS. 2 to 12 provide an overview of a structure of the photonic device used in accordance with an exemplary embodiment, FIGS. 13A to 24 illustrate experimental and simulation results in relation to device characterisation, particularly in relation to its polarimetric detection, FIGS. 25 to 29 illustrate results for validating the artificial anisotropy of the nanoantenna and polarization dependence of the photonic device, and FIGS. 30A to 38 provide results in relation to spectroscopic sensing using an embodiment of the photonic device.

In the exemplary embodiments as follow, graphene is used as the 2D material of choice for the photonic device given its zero bandgap and broadband absorption material characteristics. However, it should be appreciated that other suitable 2D materials, such as Palladium diselenide (PdSe2) or black phosphorous may be used.

### Nanoantenna-Mediated Graphene Photodetectors

FIG. 2 is a schematic perspective view showing a photonic device 200 comprising nanoantennas 202 which act as non-centrosymmetric centres formed on top of a graphene layer in accordance with an embodiment. As shown in FIG. 2, each of the nanoantennas 202 comprises two L-shape structures, each of the two L-shape structures having a first section 206 and a second section 208 perpendicular to the first section, wherein the two L-shape structures are arranged adjacent to each other with a gap in-between them, and wherein the first sections 206 of each of the two L-shape structures are on a longitudinal axis of the photonic device (i.e. along a x-axis as shown in relation to FIG. 2) and the second sections 208 of each of the two L-shape structures are parallel to each other and on a same side of the longitudinal axis so that the two L-shape structures are symmetrical with respect to a transverse axis of the photonic device (i.e. along a y-axis as shown in relation to FIG. 2), the transverse axis being perpendicular to the longitudinal axis. In the present embodiment, the nanoantennas 202 are formed by a 4 nm-thick palladium (Pd)/60 nm-thick gold (Au) bilayer structure, although it should be appreciated that other suitable metal layer or metal layers of different thicknesses may be used. For example, aluminum (Al), or silver (Ag) with Pd as an adhesion layer, may be used.

The nanoantennas 202 formed artificial sub-wavelength periodic structures, where metal plasmons generated by the nanoantennas 202 in the presence of the incident polarized light help to achieve light confinement. This enhances a local electric field of the nanoantennas 202 by several orders and increases an absorption as well as light-matter interactions associated with the photonic device 200. Furthermore, the nanoantennas 202 serve as small metal electrodes to collect carriers and thus give rise to the photocurrent. Under uniform illumination of a polarized light 210, directional photocurrents can be generated from each of the nanoantennas acting as non-centrosymmetric meta-atom at zero bias (VDS=Vg=0 V). A net photocurrent is generated under uniform illumination of the polarized light due to artificial anisotropy provided by the nanoantennas. The following embodiments were performed under zero bias unless otherwise specified.

To form the photonic device of the present embodiment, graphene flakes were mechanically exfoliated from natural graphite crystals and provided onto a top of a substrate 212 comprising a 285-nm-thick thermal SiO2 formed on a Si wafer. Alignment marks were then patterned using electron-beam lithography (EBL) and formed by depositing titanium (Ti) and gold (Au) using an electron-beam (E-beam) evaporator followed by a standard lift-off process. The device areas 214 of the graphene flakes were then patterned using EBL and the residual graphene was removed by oxygen plasma. After that, the metal nanoantennas 202 and the source and drain electrodes 216, 218 comprising Pd (4 nm-thick) and Au (60 nm-thick) were deposited on top of the patterned graphene layer 214 using EBL and the E-beam evaporator followed by the standard lift-off process.

FIG. 3 shows an atomic force microscopy (AFM) image 300 of one of the graphene flakes used in fabricating the photonic device 200 of FIG. 2 in accordance with an embodiment. The right side of the image 300 shows the graphene layer 302 and the left side of the image 300 shows the substrate 304. The intersection between the graphene layer 302 and the substrate 304 is shown by a line 306. The measured thickness of the multi-layer graphene flake using atomic force microscopy (AFM) images as shown in relation to FIG. 3 is about 1.8 nm. This indicates that the graphene layer 302 includes around 5-6 graphene sheets.

FIG. 4 shows a schematic diagram 400 of a cross-section of the photonic device 200 of FIG. 2 in accordance with an embodiment.

As shown in FIG. 4, to form the photonic device of the present embodiment, a graphene layer 402 is formed on a substrate 404. In the present embodiment, the substrate 404 comprises a layer of silicon dioxide (SiO₂) deposited on a Si wafer. A source electrode 406 and a drain electrode 408 are formed on the graphene layer 402. The source electrode 406 and the drain electrode 408 are used to measure a photovoltage generated by the photonic device 200. In an embodiment, the source electrode 406 is connected to ground and so the voltage measured at the drain electrode 408 provides the drain-source voltage (Vds). Further, an array of nanoantennas 410 are formed on the graphene layer 402, where each of the nanoantennas 410 act as non-centrosymmetric meta-atom for generating a photocurrent in response to an incident polarized light 412 on the photonic device 200. The photonic device in the present embodiment is also provided with a gate electrode 414 which allows a gate voltage Vg to be applied to the photonic device if necessary. The gate voltage can be used to modulate the drain-source current (Ids) flowing through the photonic device 200. Although the gate electrode 414 is shown to form at an entire bottom portion of the substrate 404, in an embodiment, the gate electrode 414 may form at part of the bottom portion of the substrate 404 as long as it provides sufficient leverage on modifying the Ids of the photonic device 200.

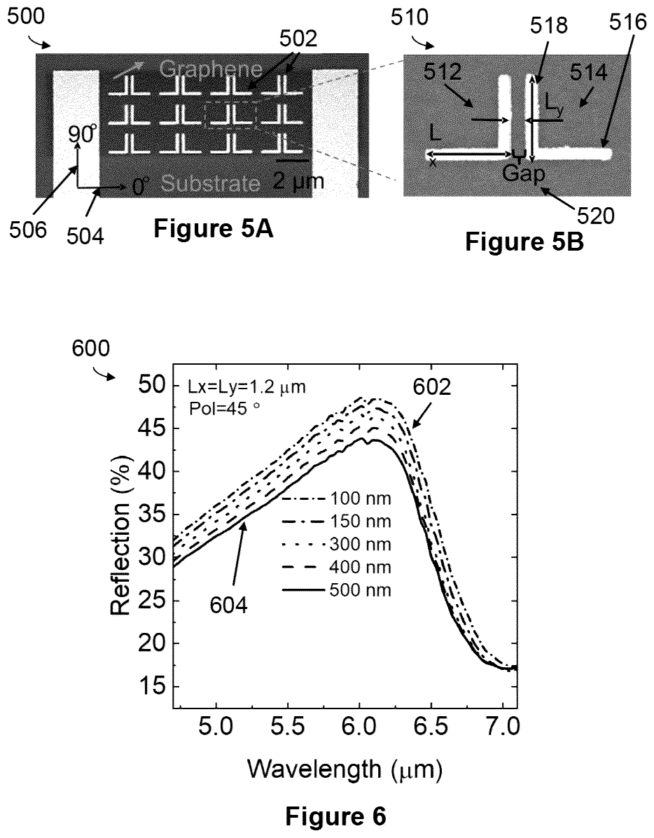

FIGS. 5A and 5B show false-colored scanning electron microscopy (SEM) images of the nanoantennas comprised in the photonic device 200 of FIG. 2 in accordance with an embodiment.

FIG. 5A shows a SEM image 500 of a top sectional view of the photonic device 200 comprising a plurality of nanoantennas 502. As shown in FIG. 5A, the plurality of nanoantennas 502 in the present embodiment includes a total of twelve nanoantennas 502 arranged into three rows of four nanoantennas. A longitudinal direction 504 of the photonic device is defined as a 0° and a transverse direction 506 of the photonic device is defined as 90°, where the longitudinal direction 504 is perpendicular to the transverse direction 506.

FIG. 5B shows a SEM image 510 of one of the nanoantennas 502 of FIG. 5A to illustrate its geometric parameters. The nanoantenna comprises two L-shape structures 512, 514. Each of the two L-shape structures 512, 514 includes a first section 516 and a second section 518 perpendicular to the first section 516. As shown in FIG. 5B, the two L-shape structures 512, 514 are arranged adjacent to each other with a gap 520 in-between them. The first section 516 is arranged in a direction along the longitudinal direction 504 or the longitudinal axis of the photonic device and the second section 518 is arranged in a direction along the transverse direction 506 or transverse axis of the photonic device. Each of the two L-shape structures 512, 514 are also arranged back-to-back with each other so that the second section of each of the two L-shape structures 512, 514 are parallel to each other and on a same side of their respective first sections 516 as shown in FIG. 5B. In other words, the two L-shape structures 512, 514 are symmetrical with respect to the transverse direction 506 of the photonic device but asymmetrical with respect to the longitudinal direction 504 of the photonic device. In the present embodiment, the nanoantennas 502 are designed to have a strong resonance at 6.5 μm, with a length of the first section Lx being 1.2 μm and a length of the second section Ly being 1.2 μm (i.e. Lx=Ly=1.2 μm) and having the gap 520 of 300 nm to avoid mutual near-field coupling. In the present embodiment, the fabricated photonic device has a dimension of 5.7×13.6 μm2 which is much smaller than the beam size. The illumination of polarized light on the photonic device can thus be regarded as uniform. Experimental results for estimating the beam size of the incident polarized light are shown in relation to FIGS. 8A and 8B below.

FIG. 6 shows a graph 600 of measured Fourier Transform Infrared (FTIR) reflection of the DLNAs with different gap distances in accordance with an embodiment. The measured FTIR reflection was obtained using DLNAs having Lx and Ly as 1.2 μm, while varying a gap distance between the two L-shape structures. An incident polarized light having a polarization angle of 45° was used.

As shown in FIG. 6, gap distances of (i) 100 nm, (ii) 150 nm, (iii) 300 nm, (iv) 400 nm and (v) 500 nm were used.

The plot 602 relates to a gap distance of 100 nm while the plot 604 relates to a gap distance of 500 nm. The other plots show a consistent trend where the measured FTIR reflection is slightly increased when decreasing the gap distance. The reflection is slightly increased when decreasing the gap distance because of the stronger plasmons induced for shorter gap distances. However, a small gap distance requires a more complicated fabrication process. In the present embodiment, a gap distance of 300 nm was used. As shown in FIG. 6, the resonant wavelength of the photonic device does not change with varying the gap distance.

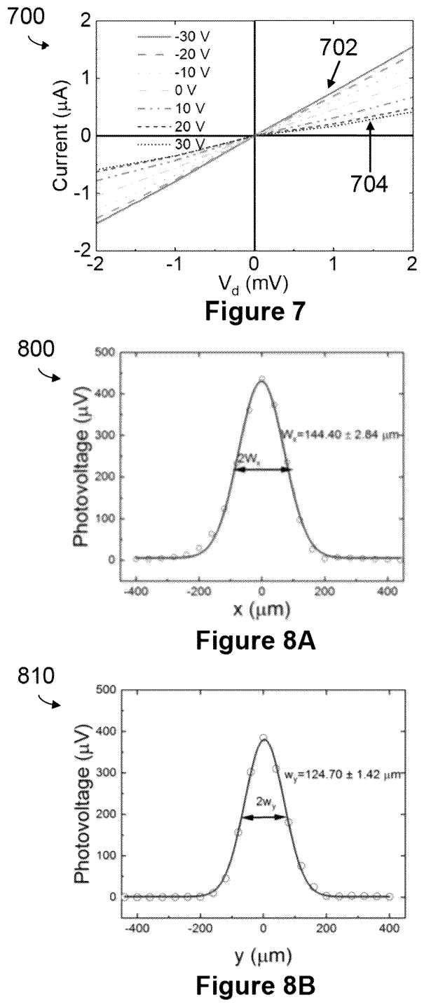

FIG. 7 shows a graph 700 of drain current (Id) versus drain-source voltage (Vd) under different gate voltages (Vg) for the photonic device of FIG. 2 in accordance with an embodiment. The different gate voltages used include (i) Vg=−30 V, (ii) Vg=−20 V, (iii) Vg=−10 V, (iv) Vg=0 V, (v) Vg=+10 V, (vi) Vg=+20 V and (vii) Vg=+30 V. The plot 702 for Vg=−30V and the plot 704 for Vg=+30V are shown as the extreme ends with the other plots showing that the device is gate voltage tunable.

In the present embodiments, the total laser beam power was measured using a power meter. Since the photonic device of the present embodiment is much smaller than the beam size, illumination of the photonic device can be regarded as uniform. The beam profile can be obtained by measuring a photovoltage output, Vph, of the photonic device due to a linear relationship between the Vph and an incident power of the incident polarized light (see for example in relation to FIG. 23 below). The power density of illumination can be calculated after obtaining the total laser power and the beam size profile. With the power density and the device area, responsivity of the photonic device can be obtained by dividing the measured photovoltage by the incident power (which is the product of power density and photodetector area). The responsivity of the graphene photonic device is calculated as 6.3 V/W in the present case.

Since the illumination spot is much larger than the photonic device, a beam size of the incident polarized light can be measured by scanning the photonic device in space. FIGS. 8A and 8B show graphs 810, 820 of photovoltage of the photonic device of FIG. 2 versus positions in relation to a x-axis and a y-axis for measuring an illumination spot size of the incident polarized light in accordance with an embodiment. As show in relation to FIGS. 8A and 8B, a full width at half maximum (FWHM) of the illumination spot were measured to be (i) 144.40±2.84 μm along the x direction and (ii) 124.70±1.42 μm along the y direction. The data points (dots) represent the experimental data with a spatial step of 40 μm, while the curves correspond to the respective Gaussian fittings of the data points.

Referring back to the photonic device of the present embodiments, the photo-response provided by the photonic device is in relation to the bulk photovoltaic effect (BPVE). The photo-response generation mechanism is discussed below. Due to the metal plasmons associated with the nanoantennas, the incident polarized light is strongly localized and its near-field intensity is extremely enhanced to generate heat to form hot spots and hot carriers at the nanoantennas. In the present case, it is considered that the photocurrent generated by the nanoantennas originates from localized hot spots formed in response to heating by the incident light and a subsequent heat flow due to inhomogeneities of the Seebeck coefficient S. Particularly, when metal nanoantennas is deposited on the graphene layer, a gradient of Seebeck coefficient, ∇S, is formed at the metal-graphene interfaces. In view of this, the photocurrent Iₚₕ can be written as Iₚₕ∝|E|². \vec{∇}S, where E is the amplitude of the electric field. Under illumination, the incident polarized light is localized to the edges of the nanoantennas due to the metal plasma localization, and the electric field is enhanced by several orders. Therefore, the photocurrent can be written in Equation (1) as:

$${I}_{p h} ∝ {\vert {E}_{en} \vert}^{2} \cdot \vert ∇ S \vert \cdot n \qquad ( 1 )$$

where Eₑₙ is the enhanced electric field and n is the normal vector of ∇S. The direction of n is along the normal of the metal-graphene interfaces, which points from graphene to metal or in the opposite direction, depending on the relative Seebeck coefficients of graphene underneath and out of the metal.

Intuitively, a photocurrent in centrosymmetric systems is zero because photocurrents from opposite directions cancel each other out. Here, a quantitative mathematical analysis is provided.

In a two-dimensional plane, the current density

$$J ( r ) = ( \begin{matrix}{J}_{x} \\ {J}_{y}\end{matrix} ) ,$$

where r is the space coordinate vector, r=xeₓ+ye_{y}, and the general expression of spontaneous of J is given in Equation 2 as:

$${J}_{a} = Σ {A}_{a b c} {E}_{b} {E}_{c}^{*} \qquad ( 2 )$$

where A is the photoresponse tensor, E is the complex amplitude of the electric field, and E* is the complex conjugate of E. a, b and c are the coordinate indices (i.e. x or y).

Equation 2 can be written in a matrix form as shown in Equation (3) as:

$$( \begin{matrix}{J}_{x} \\ {J}_{y}\end{matrix} ) = ( \begin{matrix}{A}_{xxx} & {A}_{xxy} & {A}_{xyx} & {A}_{xyy} \\ {A}_{yxx} & {A}_{yxy} & {A}_{yyx} & {A}_{yyy}\end{matrix} ) ( \begin{matrix}{E}_{x} {E}_{x}^{*} \\ {E}_{x} {E}_{y}^{*} \\ {E}_{y} {E}_{x}^{*} \\ {E}_{y} {E}_{y}^{*}\end{matrix} ) \qquad ( 3 )$$

In a centrosymmetric system, the current density is given by J(r)=−J(−r), E(r)=−E(−r), while the photo-response tensor matrix A should remain the same because A is related to a structural symmetry. A centrosymmetric system is only possible when A=0. Therefore, the photocurrent density J(r) is zero in centrosymmetric systems.

To obtain a non-zero photocurrent, non-centrosymmetry is introduced using the DLNAs. Under uniform illumination of linearly polarized light, the DLNAs serve as non-centrosymmetric meta-atoms, and the photocarriers of each meta-atom shift and form the photocurrents. The direction and magnitude of generated photocurrent are controlled by the polarization angle (θ) of the incident light.

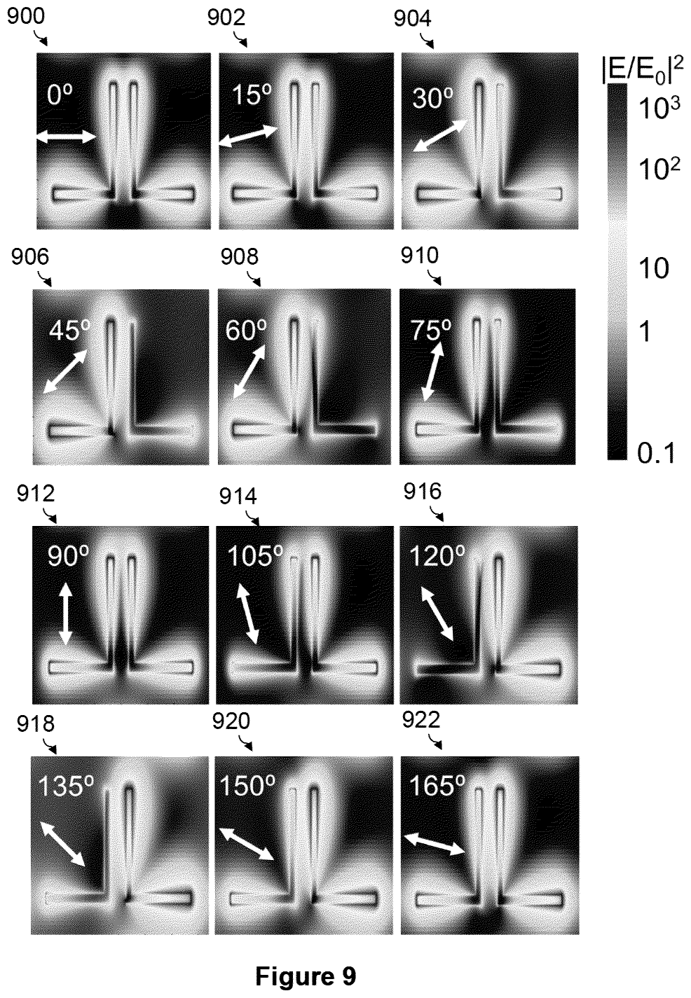

FIG. 9 shows results of simulated near-field intensity for different polarization angles of an incident polarized light in accordance with an embodiment. FIG. 9 shows simulated near-field intensity diagrams 900, 902, 904, 906, 908, 910, 912, 914, 916, 918, 920, 922 for twelve different polarization angles of the incident polarized light, namely (i) 0°, (ii) 15°, (iii) 30°, (iv) 45°, (v) 60°, (vi) 75°, (vii) 90°, (viii) 105°, (ix) 120°, (x) 135°, (xi) 150° and (xii) 165°, respectively. The angle is measured with respect to the x-axis (or longitudinal axis of the photonic device) as shown in relation to FIGS. 2 and 5A.

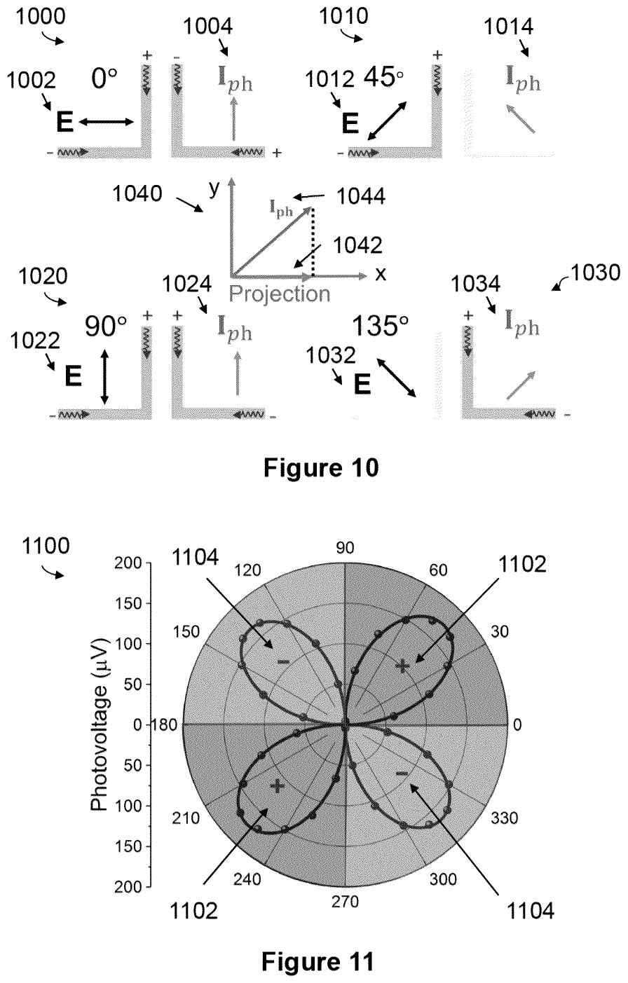

FIG. 10 shows schematic diagrams illustrating simulated plasmonic modes (e.g. curly arrows) and respective predicted vectorial photocurrents at different polarization angles of an incident polarized light in accordance with an embodiment. Four schematic diagrams 1000, 1010, 1020, 1030 in relation to four different polarization angles, (i) 0°, (ii) 45°, (iii) 90°, (iv) 135° are shown. The alternating electric field generated by the incident linearly polarized light is shown as 1002, 1012, 1022 and 1032, respectively, for the four polarization angles of (i) 0°, (ii) 45°, (iii) 90°, (iv) 135°. Simulated plasmonic modes and respective predicted vectorial photocurrents 1004, 1014, 1024 and 1034 are also shown for the respective polarization angles of (i) 0°, (ii) 45°, (iii) 90°, (iv) 135° for each unit nanoantenna. The curly arrows and the ‘+’ and ‘−’ signs as shown in FIG. 10 relate to the plasmonic modes. An inset 1040 in the middle of FIG. 10 shows experimentally measured photocurrent Iₚₕ 1042, which is a scalar projection of Iₚₕ 1044 along the x-axis (i.e. a longitudinal axis of the photonic device passing through the source-drain electrodes).

FIGS. 9 and 10, together, show the simulated near-field intensities, plasmonic modes, and the respective predicted vector photocurrents in a unit nanoantenna for different polarization angles of the incident polarized light.

As shown in relation to FIGS. 9 and 10, the incident polarized light is localized at the edges of the metal nanoantenna, where the local electric field is enhanced by ˜3 orders. At a polarization angle of 0° or 90°, an asymmetric plasmonic mode or a symmetric plasmonic mode is excited respectively, with both the left and the right L-shape structures of the nanoantenna being excited as shown in relation to FIG. 9. Due to plasmons of the metal nanoantennas, the incident polarized light is strongly localized as shown in FIG. 9 and a near-field intensity of the nanoantennas is extremely enhanced to generate heat to form hot spots and hot carriers in the nanoantennas. The photocurrents originate from these local hot spots. In the present case, photocarriers of these photocurrents can gain their momentum through two possible ways. A first way is via the hot carriers which are driven through the gradient of the Seebeck coefficient at the metal-graphene interface as discussed above. A second way is via the guidance of high conductance of the metal nanoantenna. Therefore, there exists horizontal photocurrents from the left (Iₓₗ) and right (Iₓᵣ) L-shape structures of the nanoantenna with opposite directions and two vertical photocurrents (Iᵥ) with the same direction from both the left and right L-shape structures. The photocurrent generated in the x direction (Iₓ) is predicted to be zero because the photocurrent from the left (Iₓₗ) and right side (Iₓᵣ) cancel each other out due to the mirror symmetry (Iₓ=Iₓₗ−Iₓᵣ=0), and only the vertical photocurrents (Iᵥ) are left. This is illustrated by the predicted vectorial photocurrents 1004 and 1024 for these two scenarios. In the present experiments, only the scalar projection of photocurrent Iₚₕ in the x direction can be measured (see e.g. in relation to the inset 1040 of FIG. 10). Therefore, a zero photocurrent (and therefore photovoltage) is expected to be measured at a polarization angle of 0° or 90° (see FIG. 11 below).

At other polarization angles, both the asymmetric and symmetric plasmonic modes are excited but with a phase delay between them. Particularly at a polarization angle of 45°, the phase delay is 0 due to symmetry, leading to a constructive interference on the left L-shape structure and destructive on the right L-shape structure. Conversely, at a polarization angle of 135°, the phase delay is π due to symmetry, leading to a destructive interference on the left L-shape structure and constructive on the right L-shape structure.

From 0° to 45°, partially constructive interference in the left L-shape structure and a partially destructive interference in the right L-shape structure ensue, and thus Iₓₗ increases with Iₓᵣ decreases and hence an absolute value |Iₓ|=|Iₓₗ−Iₓᵣ| as measured experimentally increases. On the other hand, from 90° to 135°, partially constructive interference in the right L-shape structure and a partially destructive interference in the left L-shape structure ensue, and thus Iₓᵣ increases with Iₓₗ decreases and hence the absolute value |Iₓ|=|Iₓₗ−Iₓᵣ| also increases.

From 45° to 90° and from 135° to 180°, the absolute value of Iₓ decreases by similar reasoning. The photocurrent at any other polarization angle (θ) is the difference between the contributions from the two eigenmodes, Iₓₗ and Iₓᵣ. In the present case, polarization angles of 45° and 135° can be taken as the two orthogonal eigenmodes because pure Iₓₗ or Iₓᵣ is achieved respectively. And thus, I(θ)=I₄₅*cos² (θ−45°)−I₁₃₅*sin² (θ−45°), where I₄₅ and I₁₃₅ are the absolute values of the photocurrent when polarization angles are at 45° and 135°, respectively. Further, it should follow that I₄₅=I₁₃₅ due to the mirror symmetry of the double L-shape nanoantenna. Hence, the photocurrent can be rewritten in Equation (4) as:

$$I ( θ ) = {I}_{45} {cos}^{2} ( θ - 45 ° ) - {I}_{45} {sin}^{2} ( θ - 45 ° ) = {I}_{45} \cdot sin ( 2 θ ) \qquad ( 4 )$$

FIG. 11 shows a polar graph 1100 of the measured photovoltages for different polarization angles of an incident polarized light in accordance with an embodiment. FIG. 11 illustrates a polarization-dependent photo-response of the photonic device, where the “+” 1102 and “−” 1104 represent the direction of photocurrent along the source-to-drain direction and opposite the source-to-drain direction respectively. The photovoltages as shown in FIG. 11 were measured using a linearly polarized light with a wavelength at 6.5 μm.

As shown in FIG. 11, the photovoltages were well-fitted using a function of sin(2θ). Particularly, the sign-flipped property of the photocurrent indicates a bipolar polarization detection and a negative polarization ratio (PR). The PR is a figure of merit in polarization detection and is usually defined as a ratio of maximum and minimum polarization-dependent photo-response. In the present case, the PR of the measured photonic device is −1, which can be leveraged for polarization-sensitive imaging. Because the photocurrent generated by un-polarized light will be zero in the photonic device of this disclosure, polarized light overwhelmed in the background of un-polarized light will be detected with high contrast. The present photonic device can be used in an integrated photonic platform to demonstrate surface-enhanced spectroscopic sensing.

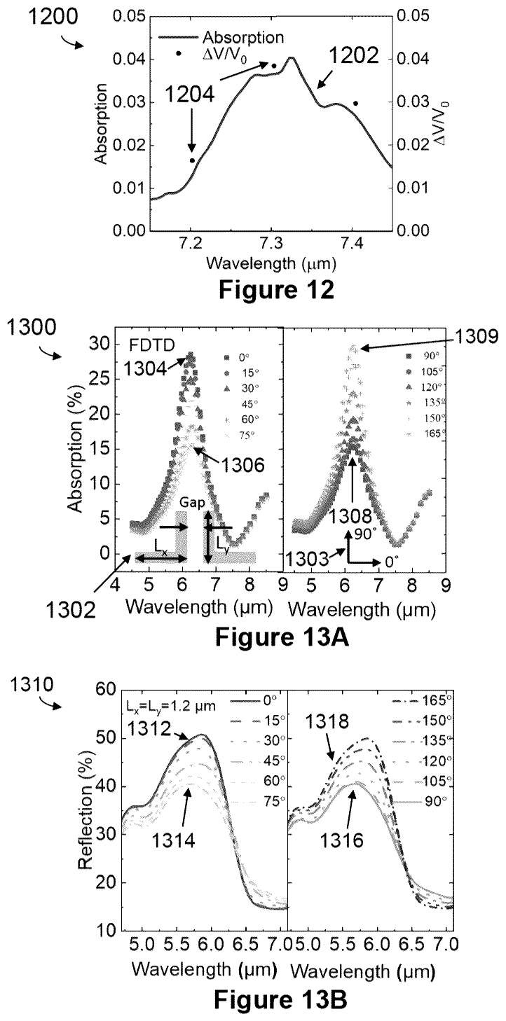

FIG. 12 shows a graph 1200 of an absorption spectrum 1202 of an acetone gas and a plot 1204 of reduction ratio ΔV/V0 versus a wavelength of an incident polarized light in accordance with an embodiment. FIG. 12 illustrates use of a photonic device of the present embodiment for spectroscopic sensing of acetone. The absorption spectrum 1202 relates to a typical acetone gas absorption spectrum as measured by a Fourier transform infrared (FTIR) spectrometer. The plot 1204 shows data points which indicate the reduction ratio of the photovoltage output of the photonic device after the entry of the acetone gas, where V0 is defined as the photovoltage output of the photonic device in the absence of the acetone gas (i.e. the analyte) which can be measured prior to the entry of the acetone gas. Acetone is used in the present example to explore the sensing performance as it is a common volatile organic compound which has an acute influence on human respiration systems and has been acknowledged as a key biomarker of diabetes.

The absorption spectrum 1202 shows that acetone has an absorption peak at around 7.3 μm. Therefore, in the present case, a photonic device having a resonance wavelength of around 7.3 μm was selected. The geometry of the L-shape structures of the nanoantenna includes Lx=1 μm and Ly=2 μm in this case. FIG. 12 demonstrates that the reduction ratio ΔV/V0 follows closely to the absorption spectrum of the acetone gas.

### Device Simulation and Characterization

FIGS. 13A and 13B show graphs 1300, 1310 of simulated absorption and reflection for different polarization angles of an incident polarized light using finite-difference time-domain (FDTD) simulation in accordance with an embodiment. The numerical simulations in this disclosure were carried out using the finite-difference time-domain (FDTD) method. The size parameters and period of nanoantennas were chosen as the same as the experimental ones for investigation. Reflection, transmission, and electric field profiles were extracted by using three frequency-domain field and power monitors.

For the present simulation, a geometric structure of the DLNAs used includes Lx=Ly=1.2 μm. This is shown in the inset 1302 of FIG. 13A. The definition of polarization angles is shown in relation to the inset 1303.

FIG. 13A shows the graphs 1300 comprising plots of simulated absorption for different polarization angles of the incident polarized light. There are twelve different polarization angles being simulated in the present case and these include (i) 0°, (ii) 15°, (iii) 30°, (iv) 45°, (v) 60°, (vi) 75°, (vii) 90°, (viii) 105°, (ix) 120°, (x) 135°, (xi) 150° and (xii) 165°. The plot 1304 relates to a polarization angle of 0° while the plot 1306 relates to a polarization angle of 75°. The other plots having a polarization angle between 0° to 75° show a consistent trend where the magnitude of absorption decreases with increasing polarization angle. On the other hand, the plot 1308 relates to a polarization angle of 90° while the plot 1309 relates to a polarization angle of 165°, and the other plots having a polarization angle between 90° to 165° show an opposite trend where the magnitude of absorption increases with increasing polarization angle.

FIG. 13B shows the graphs 1310 comprising plots of simulated reflection for different polarization angles of the incident polarized light. The plot 1312 relates to a polarization angle of 0°, the plot 1314 relates to a polarization angle of 75°, the plot 1316 relates to a polarization angle of 90°, and the plot 1318 relates to a polarization angle of 165°. The simulated reflection shows similar trends as the simulated absorption as shown in relation to FIG. 13A. In particular, the magnitude of reflection decreases with increasing polarization angle from the polarization angle of 0° to 75°, and increases with increasing polarization angle from the polarization angel of 90° to 165°. The absorption and reflection plots of FIGS. 13A and 13B also demonstrate that the resonant wavelength of the photonic device remains almost unchanged at different polarization angles.

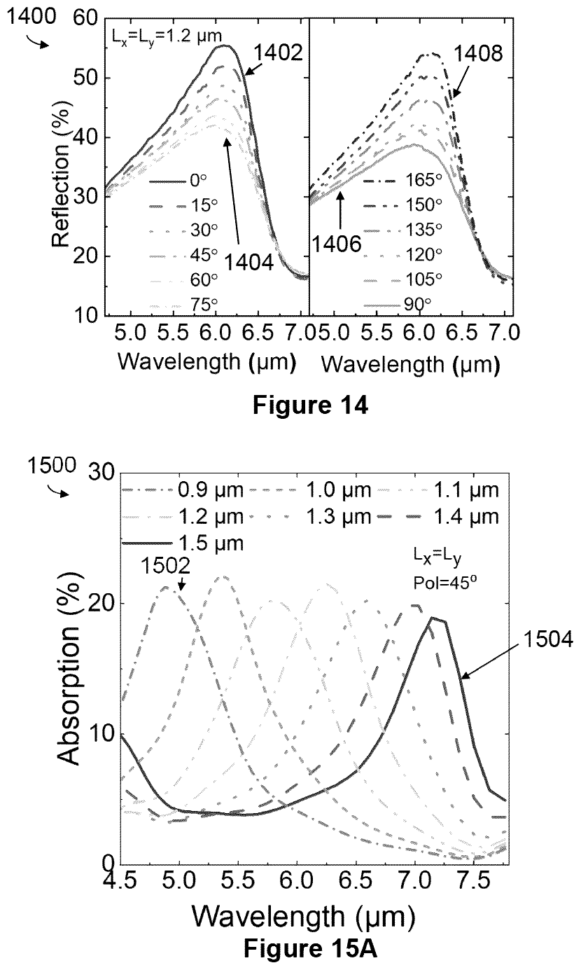

FIG. 14 shows graphs 1400 of measured reflection for different polarization angles using a Fourier Transform Infrared (FTIR) spectrometer in accordance with an embodiment. The plot 1402 relates to a polarization angle of 0°, the plot 1404 relates to a polarization angle of 75°, the plot 1406 relates to a polarization angle of 90°, and the plot 1408 relates to a polarization angle of 165°. The measured reflection shows similar trends as the simulated reflection as shown in relation to FIG. 13B, thereby validating the simulation results.

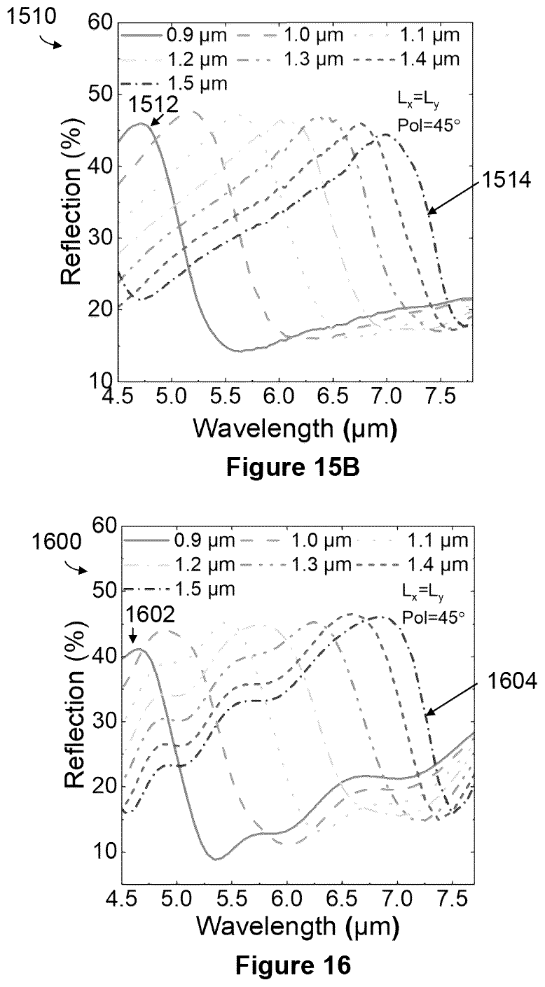

Tuning resonant wavelengths can be achieved by controlling the antenna lengths. This is shown in relation to FIGS. 15A, 15B and 16 below. In the present simulation and experiments, Lx is kept to be equal to Ly for all nanoantenna structures (i.e. Lx=Ly), and is varied from 0.9 μm to 1.5 μm.

FIGS. 15A and 15B show graphs 1500, 1510 of simulated absorption and reflection for different antenna lengths (Lx and Ly) using an incident polarized light having a polarization angle of 45° using finite-difference time-domain (FDTD) simulation in accordance with an embodiment.

FIG. 15A shows a graph 1500 of simulated absorption for the different antenna lengths (Lx and Ly) and FIG. 15B shows a graph 1510 of simulated reflection for the different antenna lengths (Lx and Ly). The plot 1502 relates to an antenna length of 0.9 μm and the plot 1504 relates to an antenna length of 1.5 μm for the simulated absorption, while the plot 1512 relates to an antenna length of 0.9 μm and the plot 1514 relates to an antenna length of 1.5 μm for the simulated reflection. For both the simulated absorption and simulated reflection, the resonant wavelengths are red-shifted with increasing antenna lengths. The control of a resonant wavelength of a photonic device using geometric parameters of the nanoantennas has therefore been demonstrated. The results of FIGS. 15A and 15B show that it is possible to fabricate an array of nanoantennas having varying geometric dimensions/parameters to provide strong resonances covering a wide LWIR range.

FIG. 16 shows a graph 1600 of measured reflection for different antenna lengths using a Fourier Transform Infrared (FTIR) spectrometer in accordance with an embodiment. The incident polarized light used has a polarization angle of 45°. The plot 1602 relates to an antenna length of 0.9 μm, while the plot 1604 relates to an antenna length of 1.5 μm. Similarly, for measured reflection using fabricated photonic devices, the resonant wavelengths are red-shifted with increasing antenna lengths. The measured reflection shows similar trends as the simulated reflection as shown in relation to FIG. 15B, thereby validating the simulation results.

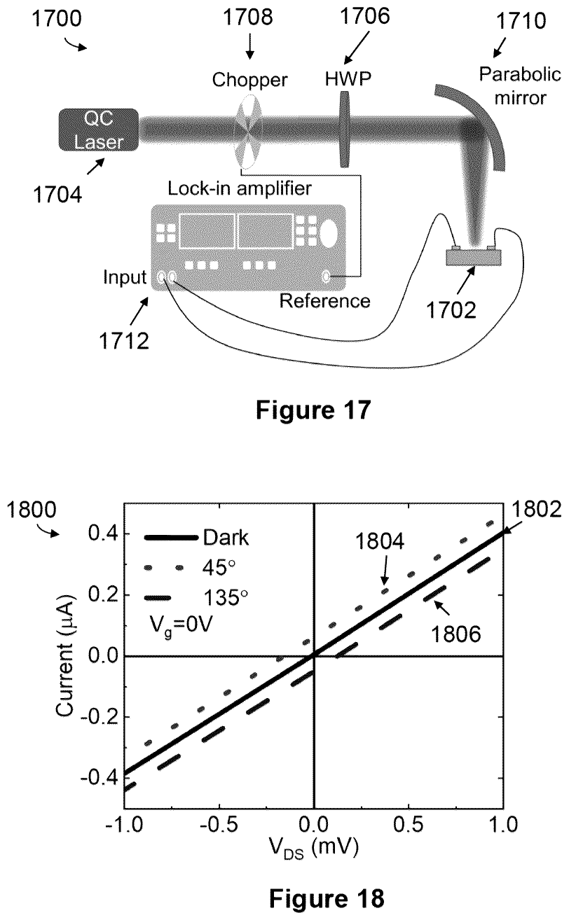

FIG. 17 shows a schematic diagram of a measurement setup 1700 for polarimetric detection using a photonic device in accordance with an embodiment. In this present embodiment, a photonic device 1702 having an array of nanoantennas with geometric parameters of Lx=Ly=1.2 μm was fabricated and used.

For the present embodiment, as shown in the measurement setup 1700, a quantum cascade laser (QCL) 1704 with a wavelength of 6.2-8.6 μm was used as the linearly polarized light source. The polarization angle was controlled by a zero order half-wave plate (HWP) 1706. Light of different frequencies was modulated using an optical chopper 1708. Id-VDS and Id-Vg curves were measured using a semiconductor characterization system. A parabolic mirror 1710 was provided in the measurement setup 1700 for redirecting and focusing the polarized light onto the photonic device 1702. In the characterization experiments, the polarization angle was always set to 45° unless otherwise stated. A lock-in amplifier 1712 was used to measure the frequency response and dark noise of the photonic device. An oscilloscope and preamplifier (not shown) were used to measure the time response. The power of the incident light was varied by using a neutral density filter and varying the laser current. The total laser power was measured by a power meter. In the present experiments, a light source of linear polarization at 6.5 μm wavelength was used.

FIG. 18 shows a graph 1800 of drain current (Id) versus source-drain voltage (VDS) of the photonic device in a dark condition, a first illuminated condition with a polarized light having a polarization angle of 45° and a second illuminated condition with a polarized light having a polarization angle of 135° using the measurement setup of FIG. 17 in accordance with an embodiment. The plot 1802 relates to the Id-VDS of the photonic device in the dark condition, the plot 1804 relates to the Id-VDS of the photonic device under the first illuminated condition, and the plot 1806 relates to the Id-VDS of the photonic device under the second illuminated condition. For this experiment, a light source of linear polarization at 6.5 μm wavelength was used, and the photonic device 1702 having an array of nanoantennas with geometric parameters of Lx=Ly=1.2 μm was measured at zero gate voltage (Vg=0).

Using the graph 1800, a resistance of the photonic device 1702 can be determined and it is about 2.6 kΩ. This reveals that Ohmic contacts between the graphene sheet and metal electrodes were formed. Also shown in FIG. 18 is that the plot 1804 is translated upwards with respect to the plot 1802 and the plot 1806 is translated downwards with respect to the plot 1802. This illustrates the opposite directions of generated photocurrents under the two different polarization angles.

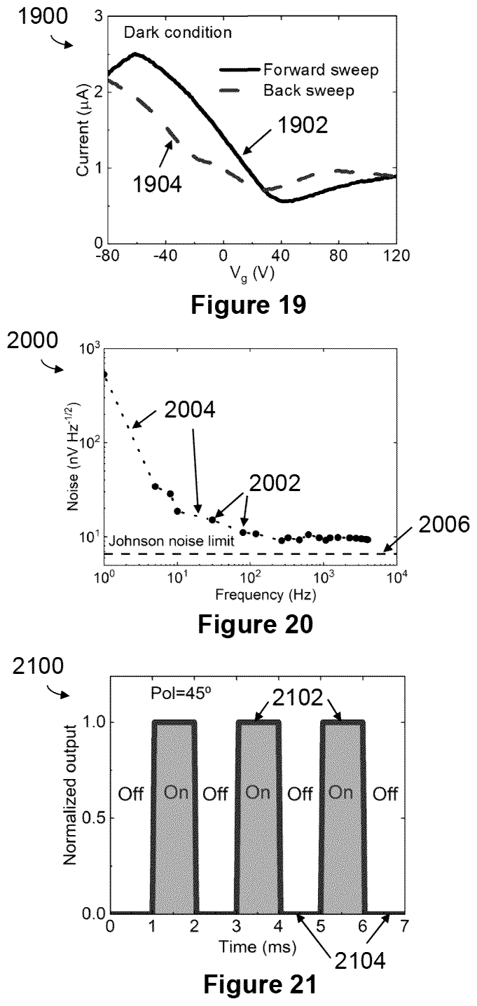

FIG. 19 shows a graph 1900 of measured drain current (Id) versus gate voltage (Vg) hysteresis curves of the photonic device 1702 of FIG. 17 in a dark condition in accordance with an embodiment. In this case, a drain-source voltage (VDS) of 3 mV was applied. The plot 1902 indicates a forward sweep (i.e. in a direction of increasing Vg) and the plot 1904 indicates a backward sweep (i.e. in a direction of decreasing Vg). The graphene is p-type doped at Vg=0 V and the neutral critical point for the photonic device 1702 is about 40 V as shown in the graph 1900.

FIG. 20 shows a graph 2000 of measured dark noise of the photonic device 1702 of FIG. 17 in accordance with an embodiment. Measured data points 2002 for the dark noise are shown in the graph 2000 with dotted lines 2004 joining these points 2002. A dash line 2006 is also shown at the bottom of the graph 2000 to indicate the Johnson noise limit. The measured dark noise as shown in the graph 2000 is mainly due to 1/f noise and Johnson noise, while the shot noise induced by dark current does not exist in this case because the photonic device 1702 was operated under zero bias. The 1/f noise is significant at frequencies below ˜100 Hz. At higher frequencies, the Johnson noise becomes dominant. Since the photonic device can be operated at speeds well beyond 100 Hz, it is not significantly affected by the 1/f noise that is dominant at low frequencies. As shown in the graph 2000, the dark noise is about 10 nV Hz-1/2 at high frequencies. From this, the noise-equivalent power (NEP) of the photonic device of the present embodiments can be obtained by dividing the dark noise by the responsivity, which is about 1.6 nW Hz-1/2.

FIG. 21 shows a graph 2100 of measured time response of the photonic device 1702 with the illumination having a polarization angle of 45° and modulated with an optical signal chopper at 1 kHz using the measurement setup of FIG. 17 in accordance with an embodiment. The shaded portions 2102 (marked as “On”) show time periods when the photonic device 1702 was illuminated, while the other portions 2104 (marked as “Off”) show time periods when the photonic device 1702 was not illuminated. Sharp edges of these different portions 2102, 2104 qualitatively indicate a fast temporal response of the photonic device to illumination.

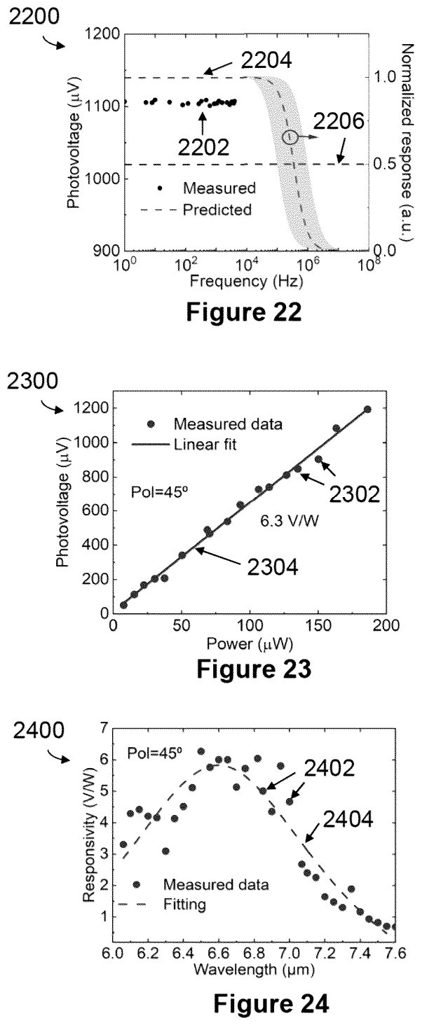

FIG. 22 shows a graph 2200 of photovoltage versus frequency for measured and predicted frequency responses of the photonic device 1702 of FIG. 17 in accordance with an embodiment. The measured data points 2202 show an almost constant photovoltage up to 4 kHz for the photonic device 1702 in this experiment (this is limited by the speed of the chopper 1708). The predicted frequency response is shown as a dotted line 2204.

The rise time (tᵣ) of the photonic device was estimated to be about 1 μs, which was estimated based on rise times obtained for similar devices having a same material and geometrical structures and fabricated using a same fabrication process (see for example devices fabricated in relation to the publication ‘Wei, J., Xu, C., Dong, B. et al. Mid-infrared semimetal polarization detectors with configurable polarity transition. Nat. Photon. 15, 614-621 (2021)’).

The rise time ty is proportional to the network time constant τ=RC, which can be obtained by deriving from

$${f}_{3 d B} = \frac{ln 9}{2 π {t}_{r}} = 350 kHz .$$

where V(t) is the voltage at time t and Vᵢ is the amplitude of the input step signal. At time t₁ and t₂, the voltages are 0.1Vᵢ and 0.9Vᵢ, respectively. Thus tᵣ=t₂−t₁=τ·ln 9. Noting that τ=RC=1/(21πf_{3 dB}), where f_{3 dB} is the frequency when voltage is down to half (3 dB). Hence the f_{3 dB} can be estimated by using the rising time tᵣ, and

$$V ( t ) = {V}_{i} ( 1 - {e}^{- \frac{r}{t}} ) ,$$

From the graph 2200, the f_{3 dB} can be read off as the frequency at which the predicted frequency response (i.e. the dotted line plot 2204) intersects with the horizontal line 2206 corresponding to a normalized response at 0.5 (i.e. where the photovoltage is down to half).

FIG. 23 shows a graph 2300 of measured photovoltage versus power of the incident polarized light at zero bias of the photonic device 1702 of FIG. 17 in accordance with an embodiment. The photovoltage of the photonic device 1702 was measured using an incident polarized light having a polarization angle of 45°. The measured data points 2302 and a linear fit 2304 are shown in the graph 2300. The graph 2300 shows that the photovoltage has a strong linear dependence on the incident power of the polarized light and the extracted responsivity is 6.3 V/W for this photonic device 1702.

FIG. 24 shows a graph 2400 of measured responsivity of the photonic device 1702 of FIG. 17 versus wavelength of the incident polarized light in the long-wave infrared (LWIR) range in accordance with an embodiment. The measured data points 2402 and a fitting 2404 to the data points 2402 are shown in the graph 2400. As shown in the graph 2400, the responsivity of the photonic device 1702 exhibits a wavelength dependence in the LWIR range. The peak around 6.5 μm relates to the resonance wavelength of the nanoantennas as designed in the photonic device 1702.

To summarize this section, it is worth noting that the noise-equivalent power (NEP) of the photonic device can be affected by many factors, such as a device temperature, device bias, an operating wavelength of the device, and a modulation frequency of the incident light. Further, responsivity of a photonic device can also be affected by the device temperature, the device bias, and the operating wavelength. Besides NEP and responsivity, there are also other figures of merits. The NEP and responsivity of the present photonic device were measured at room temperature, in the LWIR range, and under zero bias. Furthermore, the present photonic device is capable of realizing this low NEP of about 1.6 nW Hz-1/2 with an incident light modulated at only 100 Hz (see e.g. FIG. 20).

### LWIR Polarimetry and Small Polarization-Angle Perturbation

To validate the artificial anisotropy and polarization dependence of the photonic devices in the present disclosure, three photonic devices with different nanoantenna structures were formed on top of a graphene layer of each of these photonic devices.

FIG. 25 shows scanning electron microscopy (SEM) images 2500, 2510, 2520 of these three different types of devices (i.e. Device 1, Device 2 and Device 3) to illustrate the artificial anisotropy provided by the non-centrosymmetric nanoantennas for providing polarization dependence of a photonic device in accordance with embodiments. The SEM image 2500 shows Device 1 with no nanoantenna formed. The SEM image 2510 shows Device 2 with an array of the double L-shape nanoantennas (DLNAs) 2512 formed on a graphene layer. The SEM image 2520 shows Device 3 with an array of double-straight nanoantennas 2522 formed on a graphene layer. The nanoantennas 2522 of Device 3 includes two rectangular strips as shown in the SEM image 2522. In the present experiment, the graphene layers of each of these three devices were divided from the same graphene flake. Device 1 and Device 2 have the same width between the two electrodes, while Device 2 and Device 3 have the same period of antennas in the x direction (i.e. in a direction of 0° as shown in the SEM image 2510).

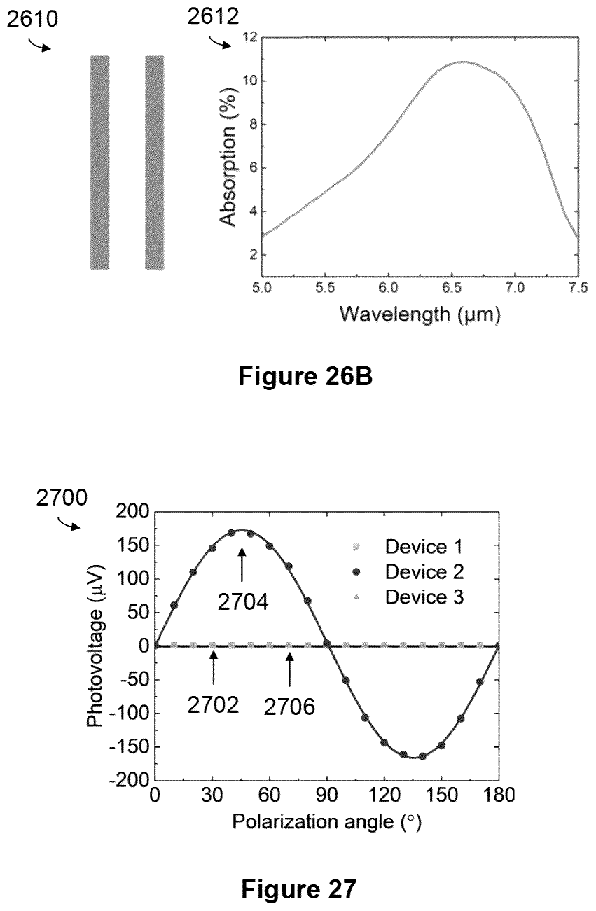

FIGS. 26A and 26B show schematic diagrams for Device 2 and Device 3 and their corresponding graphs of simulated absorption spectrums respectively using an incident polarized light having a polarization angle of 90° in accordance with an embodiment.

FIG. 26A shows a schematic diagram 2600 of a double L-shape nanoantenna structure for Device 2, and its corresponding simulated absorption spectrum is shown in the graph 2602. FIG. 26B shows a schematic diagram 2610 of a double straight nanoantenna structure for Device 3, and its corresponding simulated absorption spectrum is shown in the graph 2612. The geometric dimensions of Device 3 are Lx=0 and Ly=2.3 μm. From the graphs 2612, it is observed that Device 3 has a resonant wavelength of around 6.5 μm.

FIG. 27 shows a graph 2700 of photovoltage versus polarization angle of an incident polarized light for the three devices of FIG. 25 in accordance with embodiments. The plot 2702 relates to the measured photovoltage of Device 1, the plot 2704 relates to the measured photovoltage of Device 2, and the plot 2706 relates to the measured photovoltage of Device 3.

As shown in the graph 2700, Device 2 demonstrates a large and polarization-dependent photovoltage, while Device 1 and Device 3 exhibit almost zero photovoltage for all polarization angles. By comparing the plot 2702 of Device 1 and the plot 2704 of Device 2, it can be concluded that the anisotropy observed is provided by the artificial nanoantenna structures. By comparing the plot 2704 of Device 2 and the plot 2706 of Device 3, the analysis that non-zero photo-response originates from the non-centrosymmetric systems is validated. It is worth noting that the photovoltage of Device 2 shows a flipped-sign property, achieving a negative polarization ratio (PR), which is unusual in other 2D materials polarization detectors based on intrinsic anisotropy.

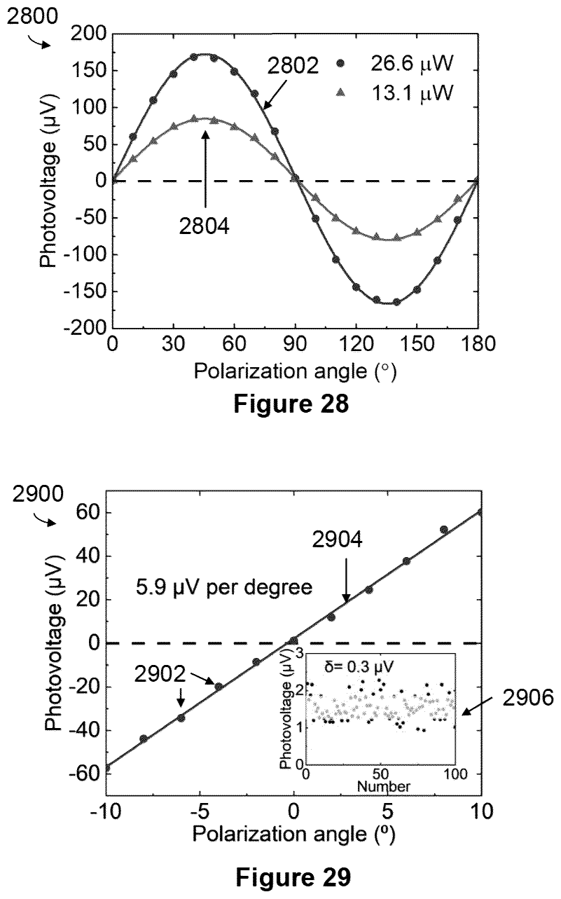

FIG. 28 shows a graph 2800 of photovoltage versus polarization angle of an incident polarized light for Device 2 of FIG. 25 using incident polarized light with two different illumination power at a wavelength of 6.5 μm in accordance with an embodiment. The plot 2802 is in relation to an incident polarized light having an illumination power of 26.6 μW and the plot 2804 is in relation to an incident polarized light having an illumination power of 13.1 μW. The plots 2802, 2804 demonstrate that Device 2 retains the polarization dependence for the measured photovoltage and the sign-flipped property even though the illumination power was decreased to half. The largest polarization-angle sensitivity is achieved at a polarization angle θ=0°, where the photo-response vanishes. The background-free operation as exemplified by the graph 2800 allows us to eliminate the laser intensity noise that is usually dominant in practical applications.

FIG. 29 shows a graph 2900 of photovoltage versus polarization angle of an incident polarized light for Device 2 of FIG. 25 with a fine polarization angle measurement of 1-degree step in accordance with an embodiment. In the measurement of small angle perturbation, the small changes in polarization angles were achieved by fine controlling the HWP 1706.

The data points 2902 for the measured photovoltages and a linear fit 2904 to these data points 2902 are shown in the graph 2900. A polarization-angle sensitivity of 5.9 μV per degree was obtained in a small range (e.g. −10° to 10° as shown in FIG. 29) near 0°. The inset 2906 shows the measured voltage fluctuation, 8=0.3 μV which was measured at a small angle close to 0°. Therefore, the limit of detection (LoD) of polarization-angle perturbation for this photonic device can be calculated as 0.05°.

### LWIR Spectroscopic Sensing

To evaluate the feasibility of utilizing photonic devices of the present disclosure for an on-chip integrated platform for LWIR polarimetric and spectroscopic sensing, acetone was selected as the analyte to examine the spectroscopic sensing performance using these photonic devices. In the present experiment, a photonic device with a resonant wavelength of around 7.3 μm with Lx=1 μm and Ly=2 μm was fabricated and used.

FIGS. 30A and 30B show diagrams in relation to the photonic device used in spectroscopic sensing in accordance with an embodiment.

FIG. 30A shows a scanning electron microscopy (SEM) image 3000 of the photonic device. Similar to the photonic device of FIG. 5A, the present photonic device includes an array of twelve double L-shaped nanoantennas 3002 arranged in three rows of four. Each of the L-shaped structures has dimensions of Lx=1 μm and Ly=2 μm.

FIG. 30B shows a graph of simulated absorption spectrum 3010 of the photonic device. The simulated absorption spectrum 3010 of this photonic device indicates that this photonic device has a resonant wavelength of around 7.3 μm. The polarization angle of incident light used was 45°.

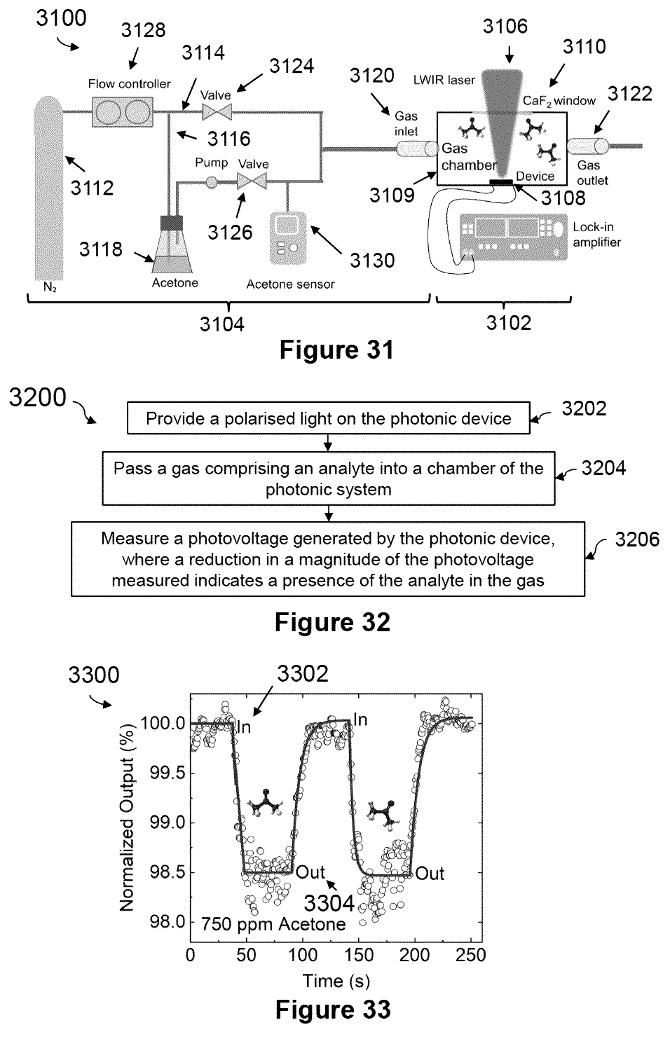

FIG. 31 shows a schematic diagram of a photonic system 3100 comprising the photonic device for spectroscopic sensing in accordance with an embodiment.

The photonic system 3100 for spectroscopic sensing can be divided into an optical characterization module 3102 and a gas regulation module 3104. For the optical characterization module 3102, a similar setup as described in relation to FIG. 17 can be used to provide an incident polarized light 3106 and to measure an output of the photonic device. In the present case, the polarization angle of the incident polarized light is fixed at 45°. The photonic device 3108 is placed in or integrated with a gas chamber 3109 with a CaF2 window 3110 to allow the passage of the incident polarized light 3106 (i.e. a LWIR laser in the present embodiment). In the gas regulation module 3104, nitrogen (N2) 3112 was selected as the buffer gas and divided into two flows 3114, 3116. A first flow 3114 was pure N2 and a second flow 3116 was pumped into an 99.5% acetone solution 3118 to produce an acetone-N2 mixture. Then, the two air flows 3114, 3116 were remixed, entering the gas chamber 3109 via a gas inlet 3120, and subsequently exiting the gas chamber 3109 via a gas outlet 3122. The concentration of acetone in the dilution could be precisely and dynamically controlled by adjusting valves 3124, 3126 using a flow controller 3128 to control the flow rates and can be accurately calibrated with one or more commercial sensors 3130 for volatile organic compounds.

FIG. 32 is a flowchart showing a method 3200 for spectroscopic sensing using the photonic system 3100 of FIG. 31 in accordance with an embodiment.

In a step 3202, a polarized light (e.g. a LWIR laser 3106) is provided on the photonic device 3108.

In a step 3204, a gas comprising an analyte (e.g. an acetone) is passed into the chamber 3109 of the photonic system 3100.

In a step 3204, a photovoltage generated by the photonic device 3108 was measured. The photovoltage can be measured using a lock-in amplifier as shown in FIG. 31. A reduction in a magnitude of the photovoltage measured indicates a presence of the analyte in the gas.

FIG. 33 shows a graph 3300 of normalized photo-response versus time measured by the photonic device 3108 of the photonic system 3100 of FIG. 31 when pure N2 and 750 ppm acetone-N2 dilution are alternately injected in the gas chamber 3109 in accordance with an embodiment. The graph 3300 shows an initial normalized output of 100%. When the 750 ppm acetone-N2 dilution was injected into the gas chamber 3109 (marked as “in” 3302), the normalized output begins to decrease up to a normalized output of 98.5% and plateau. When the 750 ppm acetone-N2 dilution was ejected out of the gas chamber 3109 (marked as “out” 3304), the normalized output increases up to 100%. A second cycle repeats. As shown in the graph 3300, a clear and repeatable drop of the photovoltage can be observed under the injection of acetone. The graph 3300 therefore illustrates a gas sensing response and recovery characteristic cycle curve of the photonic device 3108 in relation to the 750 ppm acetone-N2 dilution.

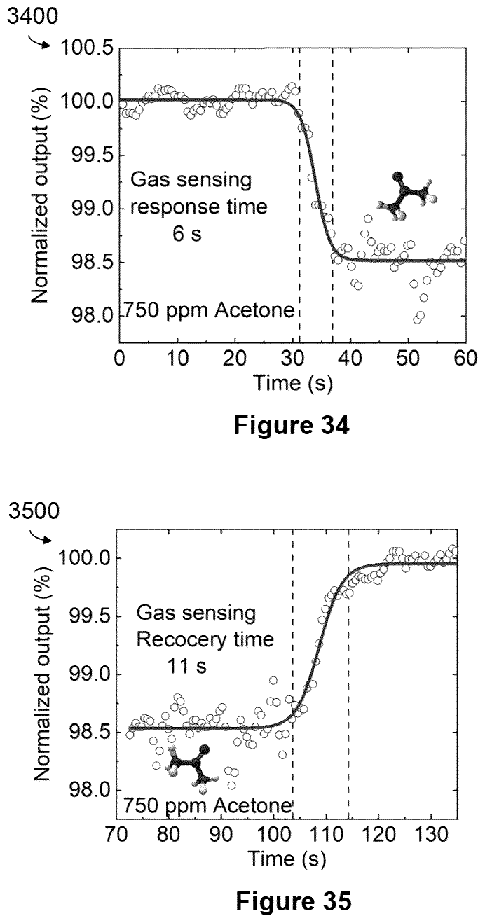

FIG. 34 shows an enlarged section 3400 of the graph 3300 of normalized photo-response versus time of FIG. 33 to illustrate a gas sensing response time of the photonic system 3100 of FIG. 31 in accordance with an embodiment. As shown in the enlarged section 3400, a gas sensing response time of 6 s was obtained.

FIG. 35 shows an enlarged section 3500 of the graph 3300 of normalized photo-response versus time of FIG. 33 to illustrate a gas sensing recovery time of the photonic system of FIG. 31 in accordance with an embodiment. As shown in the enlarged section 3500, a gas sensing recovery time of 11 s was obtained.

The gas sensing response time of 6 s and the gas sensing recovery time of 11 s of the photonic device 3108 in the present embodiment is sufficiently fast for real-time on-chip monitoring applications.

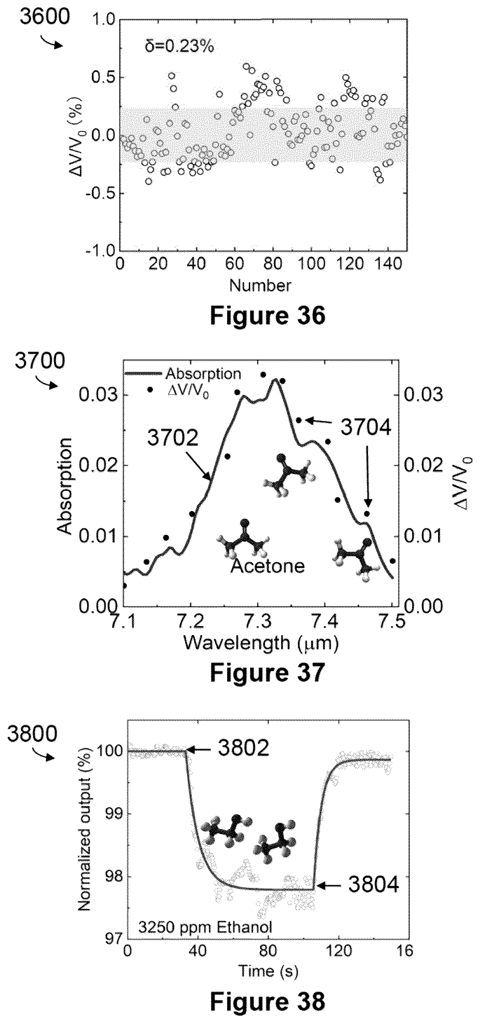

FIG. 36 shows a plot 3600 of reduction ratio ΔV/V0 using pure N2 (i.e. without acetone) to illustrate a noise level of the photonic system 3100 of FIG. 31 in accordance with an embodiment. The standard error σ obtained using the plot 3600 is around 0.23% and the corresponding 1−σ limit of detection (LoD) is about 115 ppm.

FIG. 37 shows a graph 3700 of an absorption spectrum 3702 of an acetone gas and a plot of reduction ratio ΔV/V0 3704 of the photonic system 3100 of FIG. 31 versus a wavelength of the incident polarized light in accordance with an embodiment. As shown in the graph 3700, the relative output drop/reduction ratio (ΔV/V0) 3704 measured using the photonic device 3108 within a small wavelength range (Δλ) matches well with the typical absorption spectrum 3702 of acetone. Therefore, it can be concluded that the relative output drop of the photonic device 3108 is due to the absorption of acetone.

Further, the sensing performance of ethanol was investigated. Ethanol has an absorption peak near 7.2 μm. As shown in FIG. 30B, the present photonic device can operate from 7.0 μm to 7.5 μm. Therefore, a photonic device having nanoantennas of similar/same geometric parameters as acetone sensing is also suitable for ethanol detection under the illumination of a polarized light with a wavelength of 7.2 μm.

FIG. 38 shows a graph 3800 of normalized photo-response versus time measured by the photonic device of the photonic system 3100 of FIG. 31 with injection and ejection of 3250 ppm ethanol in the gas chamber 3109 in accordance with an embodiment. Similar to the graph 3300 of FIG. 33, the graph 3800 shows an initial normalized output of 100%. When the 3250 ppm ethanol was injected into the gas chamber 3109 (marked as 3802), the normalized output begins to decrease up to a normalized output of 97.8% and plateau. When the 3250 ppm ethanol was ejected out of the gas chamber 3109 (marked as 3804), the normalized output increases up to 100%. As shown in the graph 3300, a clear and recoverable drop of the photovoltage is therefore observed under the injection and ejection of 3250 ppm ethanol.

To conclude, in the exemplary embodiments as described above, a nanoantenna-mediated graphene photodetector (NMGPD) was provided. The near-field distribution provided by the nanoantennas enhances responsivity of the photodetector and generates a strong photo-response. Particularly, embodiments of the photodetector demonstrate a high responsivity of 6.3 V/W under zero bias (VDS=Vg=0) at room temperature with a low noise-equivalent power of 1.6 nW Hz-1/2. The zero-bias operating condition makes the photodetector to be self-sustaining and low-power-consuming. Further, polarization detection is enabled by an artificial near-field anisotropy provided by the double-L shaped nanoantennas, thereby realizing filterless polarization-sensitive detection. The photodetectors of the exemplary embodiments achieve a subtle polarization-angle detection down to 0.05°, as a result of the unusual negative polarization ratio of −1. The negative polarization ratio achieved, which is unusual in the 2D materials polarization detectors based on intrinsic anisotropy, enables these photodetectors to be self-contained balanced detectors. It is also demonstrated that these graphene photodetectors are capable of spectroscopic sensing. In the present examples, acetone was chosen as the analyte for spectroscopic sensing. These graphene photodetectors show a low limit of detection (LoD) of 115 ppm, and a fast gas sensing response and recovery time of 6 s and 11 s, respectively, which makes it suitable for real-time monitoring. Moreover, these graphene photodetectors are also capable of sensing ethanol. This provides on-chip spectroscopic sensing with low limit of detection and fast dynamic response with no need for bulky and expensive spectrometers. The present disclosure therefore demonstrates the potential of these photodetectors for use as a multi-functional on-chip miniaturized monolithic integrated optoelectronic platform for polarimetric and spectroscopic sensing, which may be applied in real-time environmental monitoring, biomedical screening, real-time health monitoring and medical applications.

Although exemplary embodiments describe a graphene photodetector, it should be appreciated that other suitable 2D materials (e.g. near zero or zero bandgap, broad absorption etc.) may be used. Further, it may be appreciated that the nanoantennas as afore-described can be used in other form of photonic devices e.g. a photovoltaic cell etc. and may not be limited to a photodetector device.

It should also be appreciated that although a double L-shape structure is used for the nanoantennas in the present embodiments, other suitable structures (e.g. T-shape and triangle shape) which provides for a near-field anisotropy and causes the nanoantenna to act as a non-centrosymmetric center to generate a photocurrent in response to a polarized light incident may be used.

It should be appreciated that the resonant wavelength of the photonic device can be tuned using geometric dimensions of the nanoantennas. Therefore, a photonic device of the present disclosure can be adapted to perform spectroscopic sensing on a specific analyte by tuning the resonant wavelength of the photonic device close to a wavelength corresponding to an absorption peak of the specific analyte. The analyte maybe in a gaseous or a liquid form.

Other alternative embodiments of the invention include: (i) a gate electrode formed at a bottom side of the substrate (i.e. opposite side to the 2D material layer) which provides an additional handle for adjusting a current flowing through the photonic device in the 2D material layer; (ii) a 2D material layer having a thickness of a monolayer up to about ten layers (e.g. up to 3 nm); (iii) a gap between the two L-shape structures being in a range of 200 nm to 600 nm; (iv) a photonic device comprising one nanoantenna, a plurality of nanoantennas or an array of nanoantennas, (v) the plurality of nanoantennas or the array of nanoantennas having varying dimensions for providing a range of resonant wavelengths of the photonic device; (vi) the nanoantennas being formed by one or more metal layers, and not limited to the Pd/Au bilayers as described; (vii) the dimensions of the nanoantenna is adapted to generate the photocurrent in response to the polarized light having a wavelength in a range of 6 μm to 14 μm; (viii) geometric parameters of the nanoantennas having Lx being equal to Ly, or Lx being not equal to Ly; (ix) analysing a fluid (e.g. a gas or a liquid) comprising an analyte, and the chamber of the photonic system can be adapted accordingly (e.g. for a liquid comprising an analyte, a thin film of liquid can be sandwiched between optically transparent slides and placed within an optical path of the incident polarized light between the polarized light and the photonic device within the chamber); (x) a window of a chamber of the photonic system being formed using other suitable material which is transparent to the polarized light used; (xi) use of other suitable materials for forming the 2D material layer, such as PdSe2 or black phosphorus; (xii) using other form of polarized light (e.g. a circularly polarized light) for detecting a presence of an analyte; (xiii) using a plurality of nanoantennas being arranged in an irregular manner (e.g. as opposed to regular arrays of nanoantennas as shown, for example, in relation to FIG. 30A); and (xiv) a light wavelength of an incident polarized light or an absorption peak of an analyte for spectroscopic sensing is within a range of ±0.1 μm, ±0.2 μm, ±0.3 μm, ±0.5 μm, ±1.0 μm or ±2.0 μm from the resonant wavelength of the photonic device, where the range is dependent on a Q-factor of the photonic device.

Although only certain embodiments of the present invention have been described in detail, many variations are possible in accordance with the appended claims. For example, features described in relation to one embodiment may be incorporated into one or more other embodiments and vice versa.

1. A photonic device comprising:
a 2D material layer formed on a substrate;
a source electrode and a drain electrode formed on the 2D material layer; and
a plurality of nanoantennas formed on the 2D material layer between the source electrode and the drain electrode, each of the plurality of nanoantennas having dimensions associated with a resonant wavelength of the photonic device and being configured to act as a non-centrosymmetric centre for providing anisotropy to generate a photocurrent in response to a polarized light incident on the photonic device, the polarized light having a light wavelength near the resonant wavelength, the plurality of nanoantennas comprising one or more metal layers;
wherein the source electrode and the drain electrode are adapted to measure a photovoltage formed by the generated photocurrent, and a reduction in a magnitude of the photovoltage measured is used to detect a presence of an analyte having an absorption peak near the resonant wavelength of the photonic device.

2. The photonic device according to claim 1, wherein the polarized light includes a linearly polarized light, a polarity and a magnitude of the photovoltage measured is dependent on a polarization angle of the linearly polarized light and are adapted to indicate a polarization of the linearly polarized light.

3. The photonic device according to claim 1, wherein the 2D material layer includes graphene.

4. The photonic device according to claim 1, wherein each of the plurality of nanoantennas comprises two L-shape structures, each of the two L-shape structures having a first section and a second section perpendicular to the first section, wherein the two L-shape structures are arranged adjacent to each other with a gap in-between them, and wherein the first sections of each of the two L-shape structures are on a longitudinal axis of the photonic device and the second sections of each of the two L-shape structures are parallel to each other and on a same side of the longitudinal axis so that the two L-shape structures are symmetrical with respect to a transverse axis of the photonic device, the transverse axis being perpendicular to the longitudinal axis.

5. The photonic device according to claim 4, wherein a length of the first section of each of the two L-shape structures and a length of the second section of each of the two L-shape structures are each in a range of 0.5 μm to 2 μm.

6. The photonic device according to claim 5, wherein the length of the first section of each of the two L-shape structures is equal to the length of the second section of each of the two L-shape structures.

7. The photonic device according to claim 4, wherein the gap between the two L-shape structures is in a range of 200 nm to 600 nm.

8. The photonic device according to claim 1, wherein the light wavelength of the polarized light or the absorption peak of the analyte is within a range of ±0.5 μm from the resonant wavelength of the photonic device.

9. The photonic device according to claim 1, wherein the plurality of nanoantennas include an array of nanoantennas and the resonant wavelength of the photonic device includes a range of resonant wavelengths, the array of nanoantennas includes nanoantennas having varying dimensions for providing the range of resonant wavelengths of the photonic device.

10. The photonic device according to claim 1, wherein the one or more metal layers includes a palladium layer and a gold layer.

11. The photonic device according to claim 1, wherein the dimensions of each of the plurality of nanoantennas is adapted to generate the photocurrent in response to the polarized light having a wavelength in a range of 6 μm to 14 μm.

12. A photonic system comprising:
a photonic device, the photonic device comprising:
a 2D material layer formed on a substrate;
a plurality of nanoantennas formed on the 2D material layer, each of the plurality of nanoantennas having dimensions associated with a resonant wavelength of the photonic device and being configured to act as a non-centrosymmetric centre for providing anisotropy to generate a photocurrent in response to a polarized light incident on the photonic device, the polarized light having a light wavelength near the resonant wavelength of the photonic device, the plurality of nanoantennas comprising one or more metal layers; and
a source electrode and a drain electrode formed on the 2D material layer, wherein the plurality of nanoantennas are formed between the source electrode and the drain electrode on the 2D material layer, the source electrode and the drain electrode being adapted to measure a photovoltage formed by the generated photocurrent;
a light source configured to provide the polarized light on the photonic device, the polarized light having a wavelength near the resonant wavelength;
a chamber having an inlet adapted to allow an inflow of a gas into the chamber, an outlet adapted to allow an outflow of the gas to exit the chamber and an optically transparent window, wherein the photonic device is provided in the chamber and the optically transparent window is adapted to allow passage of the polarized light on the photonic device; and
a measurement device connected to the source electrode and the drain electrode for measuring the photovoltage generated by the photonic device, wherein a reduction in a magnitude of the photovoltage measured is used to detect a presence of an analyte in the gas, the analyte having an absorption peak near the resonant wavelength of the photonic device.

13. The photonic system according to claim 12, wherein the polarized light includes a linearly polarized light, a polarity and a magnitude of the photovoltage measured using the photonic device is dependent on a polarization angle of the incident linearly polarized light and are adapted to indicate a polarization of the linearly polarized light.

14. The photonic system according to claim 12, wherein the 2D material layer includes graphene.

15. The photonic system according to claim 12, wherein each of the plurality of nanoantennas comprises two L-shape structures, each of the two L-shape structures having a first section and a second section perpendicular to the first section, wherein the two L-shape structures are arranged adjacent to each other with a gap in-between them, and wherein the first section of each of the two L-shape structures are on a longitudinal axis of the photonic device and the second section of each of the two L-shape structures are parallel to each other and on a same side of the longitudinal axis so that the two L-shape structures are symmetrical with respect to a transverse axis of the photonic device, the transverse axis being perpendicular to the longitudinal axis.

16. The photonic system according to claim 15, wherein a length of the first section of each of the two L-shape structures and a length of the second section of each of the two L-shape structures are each in a range of 0.5 μm to 2 μm.

17. The photonic system according to claim 15, wherein the gap between the two L-shape structures is in a range of 200 nm to 600 nm.

18. The photonic system according to claim 12, wherein the light wavelength of the polarized light or the absorption peak of the analyte is within a range of ±0.5 μm from the resonant wavelength of the photonic device.

19. The photonic system according to claim 12, wherein the plurality of nanoantennas include an array of nanoantennas and the resonant wavelength of the photonic device includes a range of resonant wavelengths, the array of nanoantennas includes nanoantennas having varying dimensions for providing the range of resonant wavelengths of the photonic device.

20. A method of spectroscopic sensing using the photonic system of claim 12, the method comprising:
providing the polarized light on the photonic device;
passing the gas comprising the analyte into the chamber; and
measuring the photovoltage generated by the photonic device to detect a presence of the analyte in the gas.
